(19) United States
(12) Patent Application Publication
(10) Pub. No.: US 2005/0186444 A1
(43) Pub. Date: Aug. 25, 2005

(54) Electroluminescent devices having conjugated arylamine polymers

(75) Inventors: Shiying Zheng, Webster, NY (US); Kathleen M. Vaeth, Rochester, NY (US); Quang Phan, Penfield, NY (US)

Correspondence Address: Pamela R. Crocker;Patent Legal Staff, East Kodak Company, 343 State Street, Rochester, NY, 14650-2201, US

(73) Assignee: Eastman Kodak Company

(21) Appl. No.: 10/786,372

(22) Filed: Feb. 25, 2004

(51) Int. Cl. H05B 33/12

(52) U.S. Cl. 428/690; 428/917; 313/504; 313/506; 257/40; 427/66

(57) ABSTRACT

An electroluminescent device, including a spaced-apart anode and cathode and an organic layer disposed between the spaced-apart anode and cathode and including a polymer having arylamine repeating unit moiety represented by formula 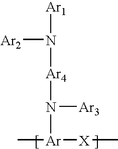 wherein:
Ar, Ar₁, Ar₂, Ar₃, and Ar₄ are each individually arylof from 6 to 60 carbon atoms; or a heteroarylof from 4 to 60 carbons, or combinations thereof; or Ar₁ and Ar₂, Ar₃ and Ar₄, Ar₁ and Ar₄, Ar₂ and Ar₄ are connected through a chemical bond; and X is a conjugated group having 2 to 60 carbon atoms.

### FIELD OF THE INVENTION

The present invention relates to electroluminescent (EL) devices having conjugated arylamine polymers.

### BACKGROUND OF THE INVENTION

Electroluminescent (EL) devices such as light emitting diode (LED) are opto-electronic devices which radiate light on the application of an electrical field. Organic materials including both polymers and small molecules have been used to fabricate LEDs. LEDs fabricated from these materials offer several advantages over other technologies, such as simpler manufacturing, low operating voltages, and the possibility of producing large area and full-color displays. Organic polymers generally offer significant processing advantages over small molecules especially for large area EL display because polymer films can be easily produced by casting from solutions.

Conjugated polymers such as poly(phenylvinylene) (PPV) were first introduced as EL materials by Burroughes et al in 1990 (Burroughes, J. H. Nature 1990, 347, 539-41). Other conjugated polymers include poly(fluorene) (PF), poly(p-phenylene) (PPP), and poly(thiophene). Due to the rigidity of the polymer backbone, the polymers are insoluble without introducing the flexible side chains. Linear or branched alkyl or alkoxy are the most commonly utilized solublizing groups. PPVs and PFs and their derivatives are among the most studied conjugated polymers because of their great potential applications in various areas including LED, photodiodes, organic transistors, and solid state laser materials. Electron donor such as alkoxy substitued PPVs show higher efficiencies than unsubstituted ones in LED applications. Other substituents have been rarely investigated. Amine groups are stronger electron donors than alkoxy groups, and amino-substituted PPVs have also been prepared to investigate the effect of amino groups on the LED efficiencies. However, only dialkylamines have been incorporated into PPV as substitutents (Stenger-Smith, J. D. et al Macromolecules 1998, 31, 7566-7569). It is known that dialkylamino groups are susceptible to oxidation.

### SUMMARY OF THE INVENTION

It is an object of the present invention to provide polymeric luminescent materials useful for EL devices.

It is a further object of the present invention to provide various energy bandgap luminescent polymers which emit broad range of color.

It is another object of the present invention to provide low ionization potential polymers useful as hole injection materials in EL devices.

These objects are achieved in an electroluminescent device, comprising:
a) a spaced-apart anode and cathode; and
b) an organic layer disposed between the spaced-apart anode and cathode and including a polymer having arylamine repeating unit moiety represented by formula 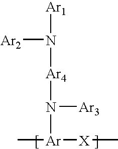
   wherein:
Ar, Ar₁, Ar₂, Ar₃, and Ar₄ are each individually aryl group of from 6 to 60 carbon atoms; or a heteroaryl group of from 4 to 60 carbons, or combinations thereof; or Ar₁ and Ar₂, Ar₃ and Ar₄, Ar₁ and Ar₄, Ar₂ and Ar₄ are connected through a chemical bond; and
X is a conjugated group having 2 to 60 carbon atoms.

The present invention provides light-emitting materials with a number of advantages that include good solubility, efficiency and stability. The emitting color of the polymer can be easily tuned by the incorporation of desired X group. Furthermore, other eletro-optical properties can also be tuned with X group. The low ionization potentials of the arylene diamine pendant side chain enable the conjugated polymers of the present invention to be useful as hole injection materials as well.

### BRIEF DESCRIPTION OF THE DRAWINGS

FIG. 1 illustrates in cross-section a basic structure of an EL device;

FIG. 2 illustrates the EL spectra of EL devices fabricated from polymer 5, 28, and 58: ITO/PEDOT/polymer/CsF/Mg:Ag;

FIG. 3 illustrates the absorption (AB) and photoluminescence (PL) spectra of polymer 5 in solution and thin film; and

FIG. 4 illustrates voltage-current density-luminance characteristic of the EL device fabricated from polymer 5.

### DETAILED DESCRIPTION OF THE INVENTION

The present invention provides polymers containing arylamine moieties with good solubility and efficiency, low driving voltage, and improved stability. Arylamine as a hole transport material in organic light-emitting devices was studied intensively due to its high hole transporting mobility, chemical and electronic stability. Arylamine moieties are strong electron donors that will improve the hole injection and transporting mobility of the polymer. Moreover, incorporating arylamine moieties into the polymer can enhance the solubility, improve polymer conductivity, and adjust polymer oxidation sensitivity. The low ionization potentials of the arylene diamine pendant side chain enable the conjugated polymers of the present invention to be useful as hole injection materials as well. Incorporation of group X described below into polymer has the following features:
1) to improve EL efficiency by achieving good balanced electron-hole injection and recombination of the charge carriers;
2) to further improve solubility of the polymer; and
3) to tune the emissive color of the polymer.

The present invention provides polymers containing arylamine moieties having the repeating unit represented by formula (I) 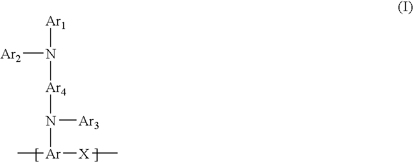
wherein:
Ar, Ar₁, Ar₂, Ar₃, and Ar₄ are each individually arylof from 6 to 60 carbon atoms; or a heteroarylof from 4 to 60 carbons, or combinations thereof; or Ar₁ and Ar₂, Ar₃ and Ar₄, Ar₁ and Ar₄, Ar₂ and Ar₄ are connected through a chemical bond.
X is a conjugated group having 2 to 60 carbon atoms. The group can include vinylenes, ethynylenes, arylenes, heteroarylenes, arylene vinylenes, heteroarylene vinylenes and combinations thereof. X can include more than one conjugated group.

For example, Ar₁, Ar₂, Ar₃, and Ar₄ represent 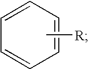
wherein:
R is a substituent being hydrogen, or alkyl, or alkenyl, or alkynyl, or alkoxy of from 1 to 40 carbon atoms; arylof from 6 to 60 carbon atoms; or heteroarylof from 4 to 60 carbons; or F, or Cl, or Br; or a cyano group; or a nitro group; or R is a group necessary to complete a fused aromatic or heteroaromatic ring;

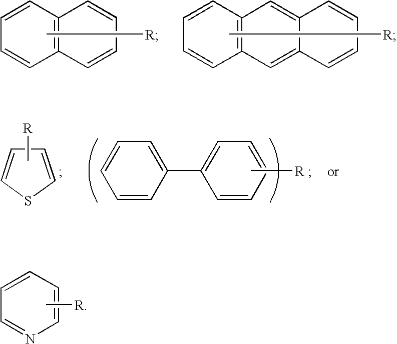

When Ar₁ and Ar₂, Ar₃ and Ar₄, Ar₁ and Ar₄, Ar₂ and Ar₄ are connected through a chemical bond, Ar₁ and Ar₂ together, Ar₃ and Ar₄ together, Ar₁ and Ar₄ together, Ar₂ and Ar₄ together contain 8 to 60 carbon atoms. For example, Ar₁ and Ar₂, Ar₃ and Ar₄, Ar₁ and Ar₄, Ar₂ and Ar₄ are connected by a chemical bond to form a group having 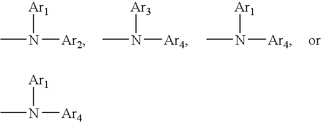
that includes the following carbazole and carbazole derivatives:

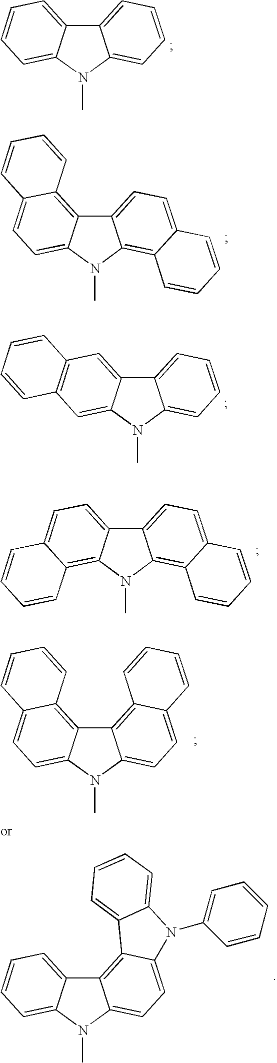

Preferably, Ar₄ is a six-member aryl or heteroaryl group and the conjugated polymers of the present invention is represented by the repeating unit of formula (II) 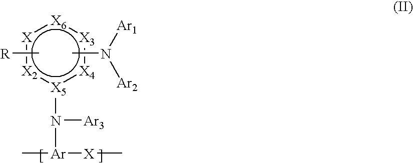
wherein:
X₁, X₂, X₃, X₄, X₅, and X₆ are individually the same or different and each include a moiety containing CH or N; and R is a substituent as defined above.
Ar represents the following groups: 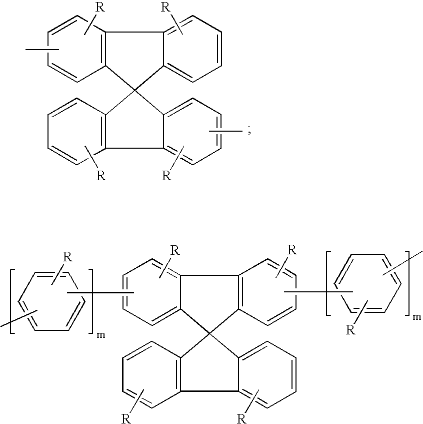
   wherein: m is an integer from 1 to 4; 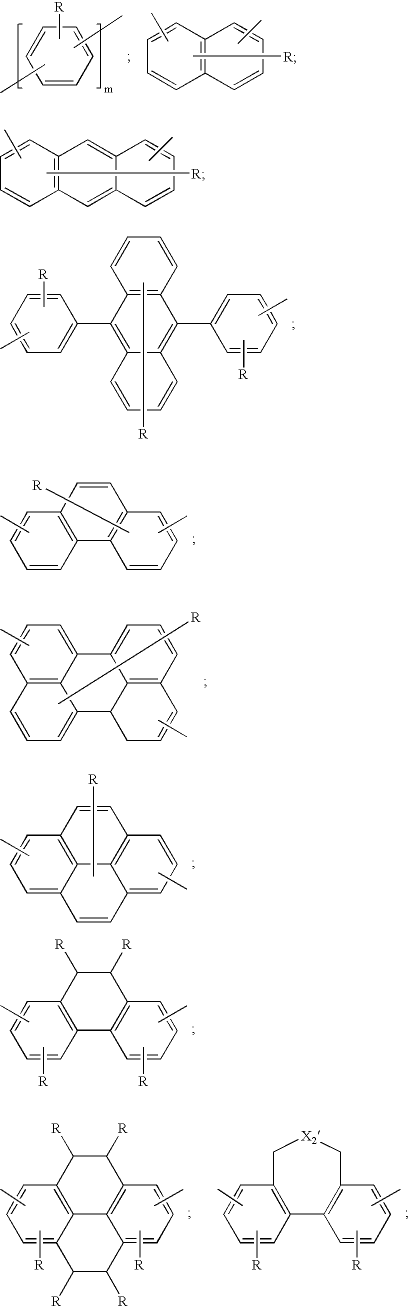
   wherein: X₂′ is S, Se, or O atom, SiR₂, or N—R; or 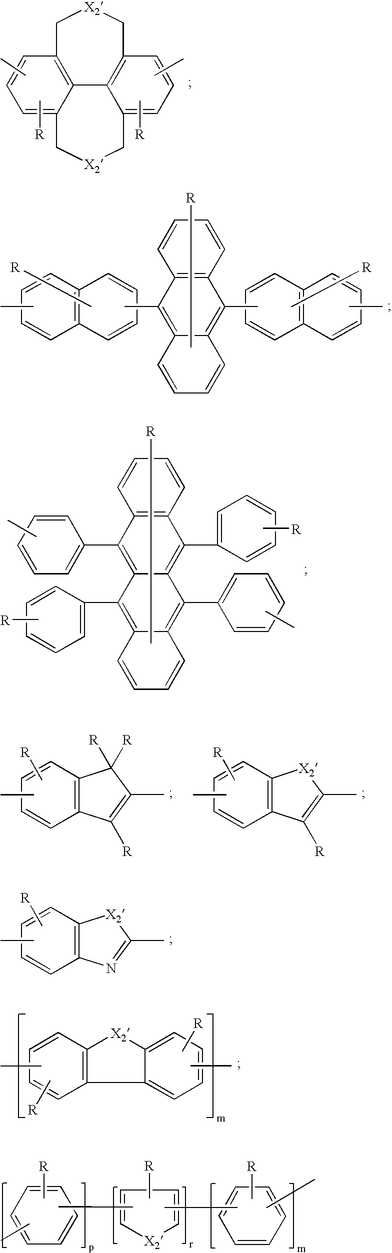
   wherein p and r are integers from 1 to 4; 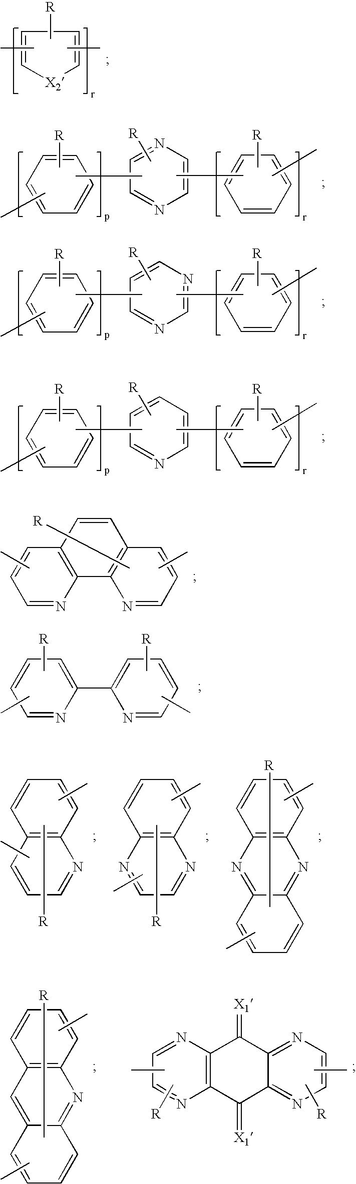
   wherein: X₁′ is an O atom or two cyano groups; 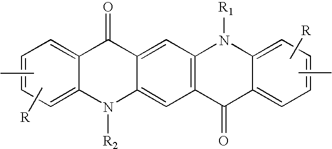
   wherein: R₁ and R₂ are individually hydrogen, or alkyl of 1 to 40 carbon atoms, or arylcontaining 6 to 60 carbon atoms; or heteroarylcontaining 4 to 60 carbons; or F, Cl, or Br; or a cyano group; or a nitro group; 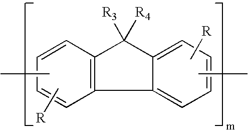
   wherein: R₃ and R₄ are substituents each being individually hydrogen, or alkyl, or alkenyl, or alkynyl, or alkoxy of from 1 to 40 carbon atoms; arylof from 6 to 60 carbon atoms; or heteroarylof from 4 to 60 carbons; or F, Cl, or Br; or a cyano group; or a nitro group;

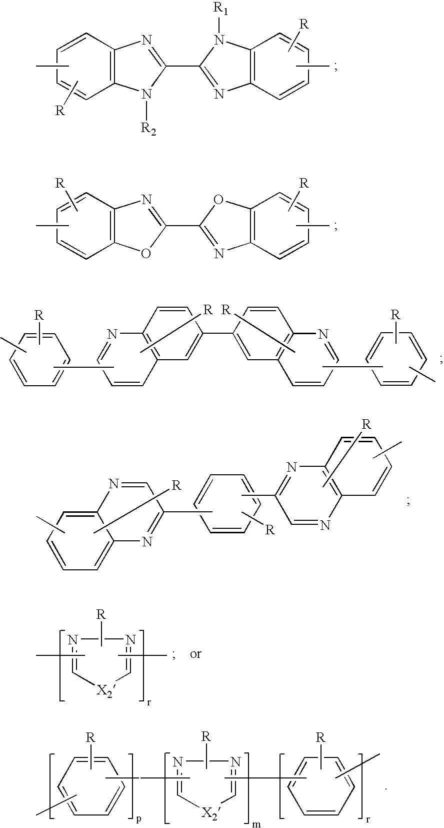

Ar can be one or the combination of more than one of the above groups.
X can be divided into the following groups.
   Group I:
X is a vinylene, or ethynylene group of formula (II):
   —W— (II)
   wherein:
W contains 2 to 40 carbon atoms, may also contains O, N, S, F, Cl, or Br, or Si atoms.

The following structures constitute specific examples of formula (II) 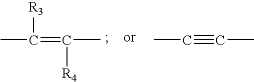
Group II:
X is a group containing two aryl or heteroaryl groups Ar₃ and Ar₄ connected by a linking group L₁ of formula (III):
   —(Ar₇)-L₁-(Ar₈)— (III)
   wherein:
Ar₇ and Ar₈ are substituted or unsubstituted aryl groups containing 6 to 60 carbon atoms, or heteroaryl groups containing 4 to 60 carbon atoms;
L₁ is a linking groups containing 0 to 40 carbon atoms, may contain N, Si, O, Cl, F, Br, or S atoms.

The following structures constitute specific examples of formula (III) 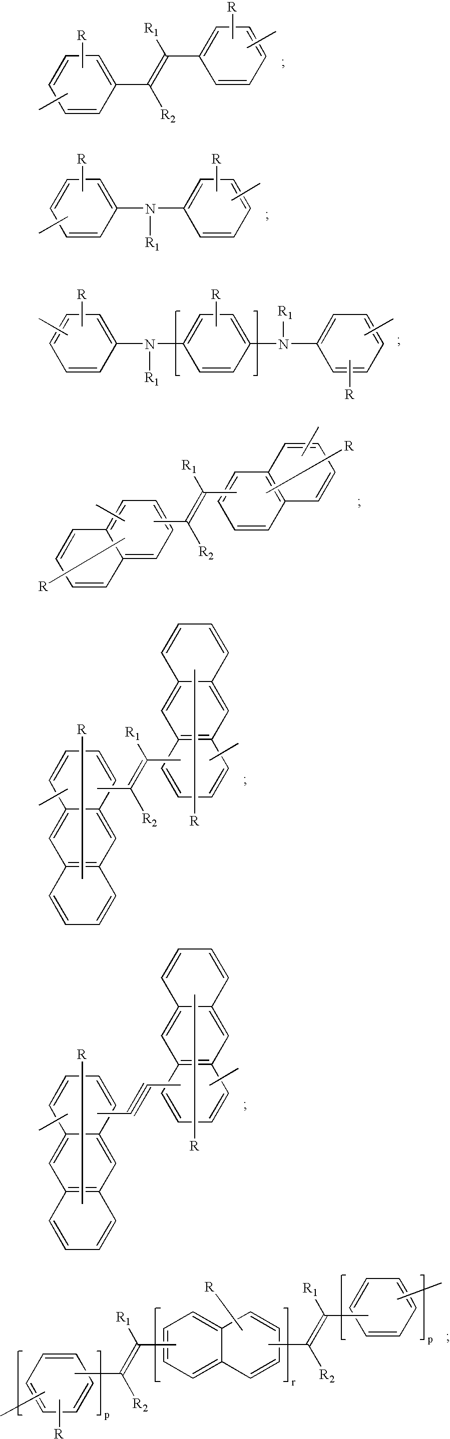 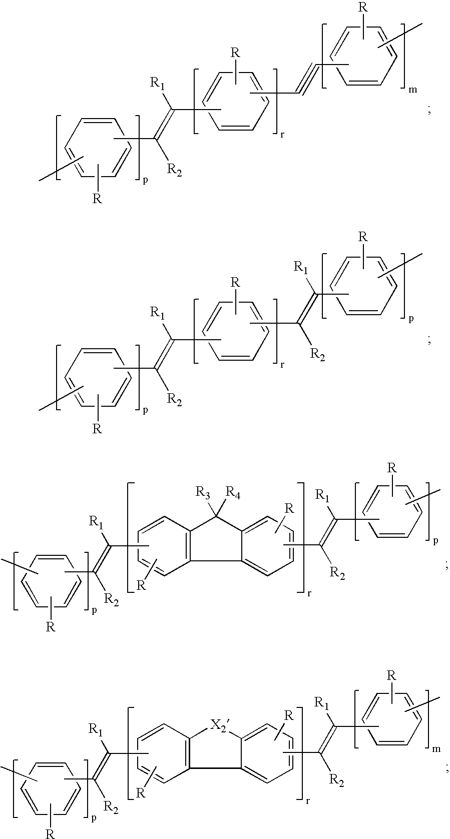
wherein: X₂ is S, Se, or O atom, SiR₂, or N—R; or; 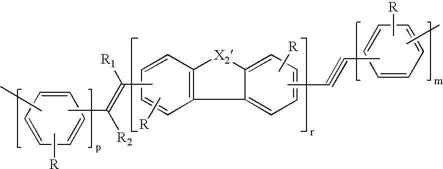
Group III:
X is an aryl or heteroaryl group of formula (IV):
   -Arg-
wherein: Ar₉ is defined as Ar as noted above.

The following molecular structures constitute specific examples of preferred compounds satisfying the requirement of this invention: 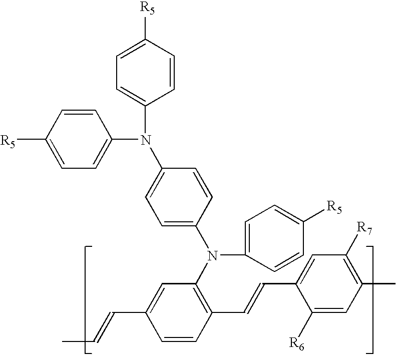
polymer 1 R₅═R₆=n-hexyl, R₇=2-ethylhexyl
polymer 2 R₅═H, R₆=R₇=3,7-dimethyloctyl
polymer 3 R₅=4-(bis(4-methylphenyl)amino)phenyl, R₆═H, R₇=t-butyl
polymer 4 R₅=4-(N-carbazole)phenyl, R₆=n-decyl, R₇═H
polymer 5 R₅═H, R₆=methoxy, R₇=3,7-dimethyloctyloxy
polymer 6 R₅═R₆=n-hexyloxy, R₇═H
polymer 7 R₅=6=R₇=n-hexyloxy 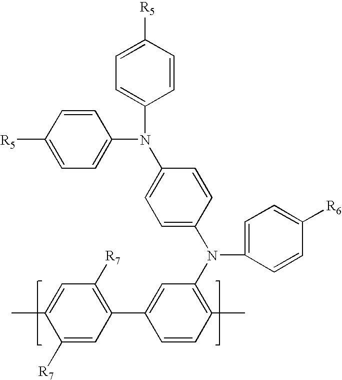
polymer 8 R₅═R₆=n-hexyl, R₇=2-ethylhexyl
polymer 9 R₅═H, R₆=R₇=3,7-dimethyloctyl
polymer 10 R₅=4-(bis(4-methylphenyl)amino)phenyl, R₆═H, R₇=t-butyl
polymer 11 R₅=4-(N-carbazole)phenyl, R₆=n-decyl, R₇═H
polymer 12 R₅=n-hexyl, R₆═R₇═H
polymer 13 R₅═R₆=n-hexyloxy, R₇═H
polymer 14 R₅═R₆═R₇=n-hexyloxy 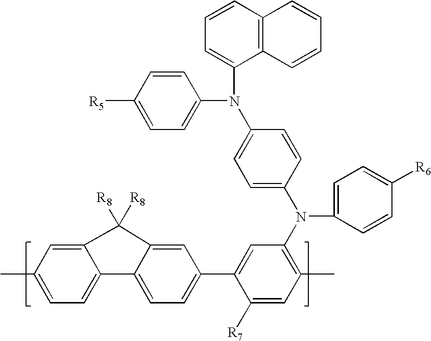
polymer 15 R₅═R₆═R₇═R₈=n-hexyl
polymer 16 R₅═R₇═H, R₆═R₈=3,7-dimethyloctyl
polymer 17 R₅═R₇═H, R₆=4-(bis(4-methylphenyl)amino)phenyl, R₈ n-hexyl
polymer 18 R₅=4-(N-carbazole)phenyl, R₆═R₈=n-decyl, R₇═H
polymer 19 R₅=n-hexyloxy, R₆═R₇=n-hexyl, R₈=n-octyl 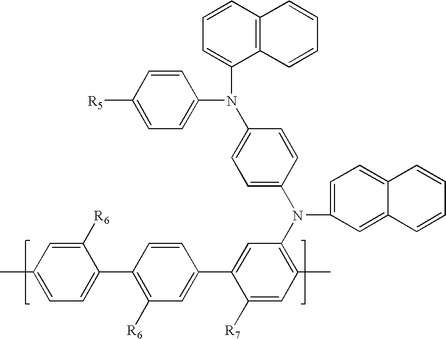
polymer 20 R₅═R₆=n-hexyl, R₇=2-ethylhexyl
polymer 21 R₅=methyl, R₆═R₇=3,7-dimethyloctyl
polymer 22 R₅=4-(bis(4-methylphenyl)amino)phenyl, R₆═H, R₇=t-butyl
polymer 23 R₅=4-(N-carbazole)phenyl, R₆=n-decyl, R₇═H
polymer 24 R₅=n-hexyl, R₆═R₇═H 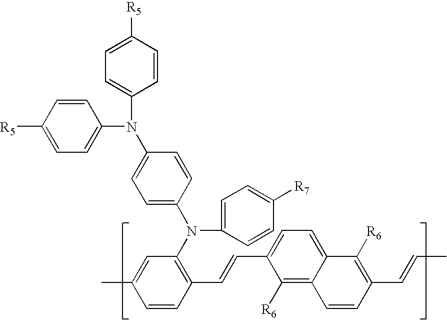
polymer 25 R₅═R₆═R₇=n-hexyl
polymer 26 R₅=n-hexyl, R₆=3,7-dimethyloctyloxy, R₇═H
polymer 27 R₅═R₇=methyl, R₆=4-(bis(4-methylphenyl)amino)phenyl
polymer 28 R₅═R₇═H, R₆=n-hexyloxy 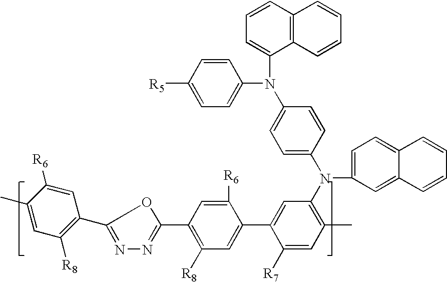
polymer 29 R₅═R₆═R₇═R₈=n-hexyl
polymer 30 R₅=n-hexyl, R₇═H, R₆═R₈=3,7-dimethyloctyloxy
polymer 31 R₅═R₇═H, R₆=4-(bis(4-methylphenyl)amino)phenyl, R₈═H
polymer 32 R₅=n-hexyloxy, R₆=n-decyl, R₇═R₈═H 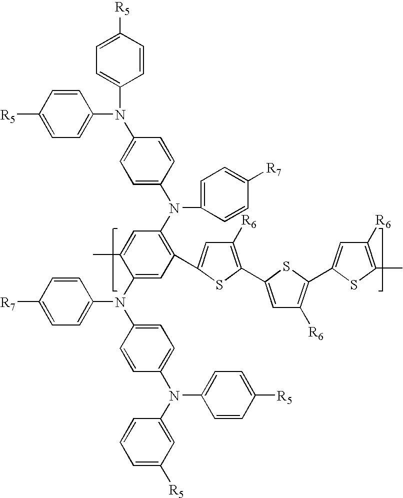
polymer 33 R₅═R₆=n-hexyl, R₇=2-ethylhexyl
polymer 34 R₅═H, R₆═R₇=3,7-dimethyloctyl
polymer 35 R₅═R₇=methyl, R₆=2-ethylhexyl
polymer 36 R₅═R₆=n-hexyl, R₇=t-butyl
polymer 37 R₅═R₇=n-hexyloxy, R₆=2-ethylhexyl 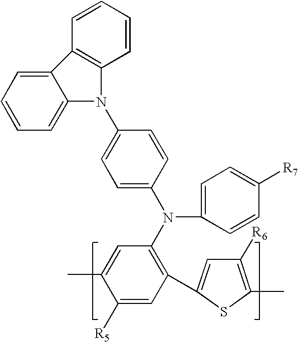
polymer 38 R₅═R₆=n-hexyl, R₇=2-ethylhexyl
polymer 39 R₅═H, R₆=n-hexyl, R₇=t-butyl
polymer 40 R₅═R₇=methyl, R₆=4-t-butylphenyl
polymer 41 R₅═R₆=n-hexyl, R₇═H
polymer 42 R₅═R₇═H, R₆=2-ethylhexyl 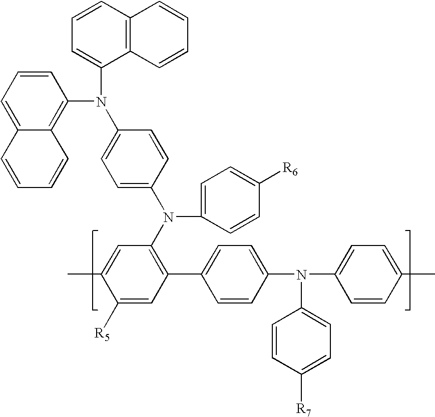
polymer 43 R₅=n-hexyl, R₆═H, R₇=n-decyl
polymer 44 R₅═R₇=2-ethylhexyl, R₆═H
polymer 45 R₅═R₆=n-hexyl, R₇=(4-carbazole)phenyl
polymer 46 R₅=n-hexyloxy, R₆═H, R₇=3,7-dimethyloctyl
polymer 47 R₅═R₆=n-hexyl, R₇=trifluoromethyl 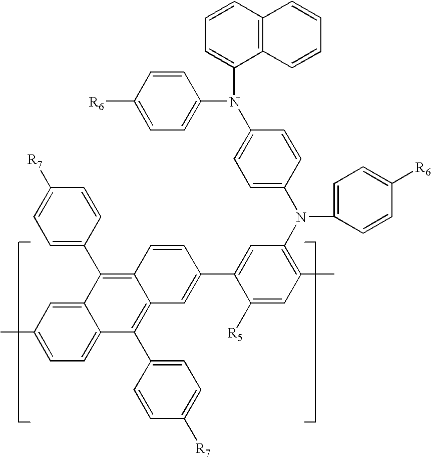
polymer 48 R₅=n-hexyl, R₆═H, R₇=t-butyl
polymer 49 R₅═R₇=3,7-dimethyloctyl, R₆═H
polymer 50 R₅═R₆═R₇=n-hexyl
polymer 51 R₅═H, R₇=n-hexyloxy, R₆=diphenylamino
polymer 52 R₅═R₆═H, R₇=trifluoromethyl 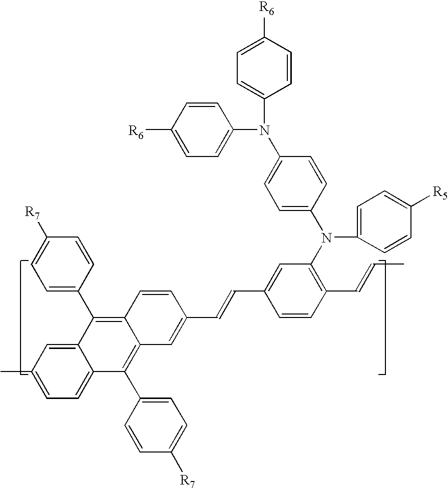
polymer 53 R₅=n-hexyl, R₆═H, R₇=t-butyl
polymer 54 R₅=n-hexyl, R₆═R₇=2-ethylhexyl
polymer 55 R₅=methyl, R₆═H, R₇=3,7-dimethyloctyl
polymer 56 R₅═R₆=n-hexyl, R₇=(4-carbazole)phenyl
polymer 57 R₅=n-hexyloxy, R₆═H, R₇=diphenylamino
polymer 58 R₅═R₆═H, R₇=2-ethylhexyloxy 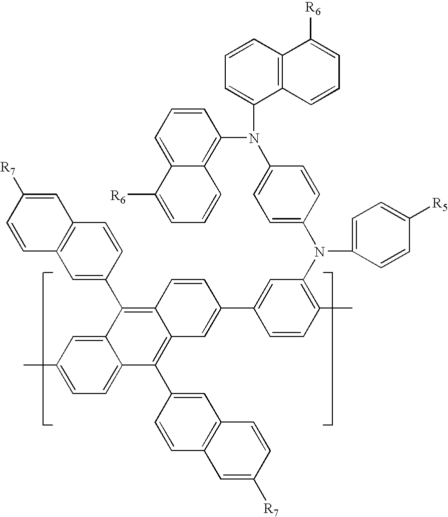
polymer 59 R₅═R₆═R₇=n-hexyl
polymer 60 R₅=n-hexyl, R₆═H, R₇=2-ethylhexyloxy
polymer 61 R₅=4-(bis(4-methylphenyl)amino)phenyl, R₆=n-hexyl, R₇=n-decyl
polymer 62 R₅═H, R₆=methyl, R₇=3,7-dimethyloctyl
polymer 63 R₅═R₇=n-hexyloxy, R₆═H 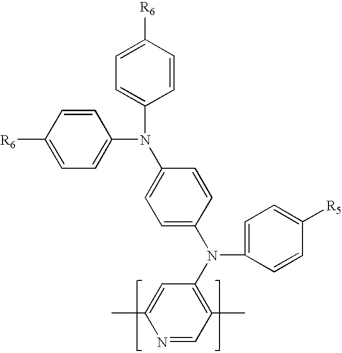
polymer 64 R₅═R₆=n-hexyl
polymer 65 R₅=n-hexyl, R₆═H
polymer 66 R₅=4-(bis(4-methylphenyl)amino)phenyl, R₆=2-ethylhexyl
polymer 67 R₅═R₆=n-hexyloxy
polymer 68 R₅═H, R₆=n-hexyloxy 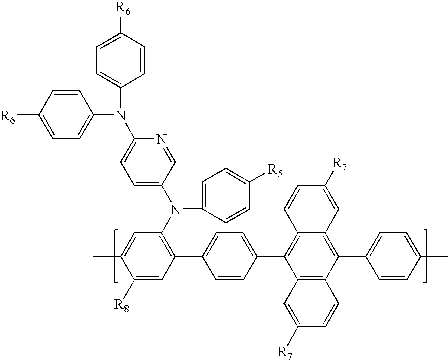
polymer 69 R₅═R₆=n-hexyl, R₇═R₈=2-ethylhexyloxy
polymer 70 R₅=n-hexyl, R₆═R₇═H, R₈=t-butyl
polymer 71 R₅═R₆⊚H, R₇═R₈=4-(bis(4-methylphenyl)amino)phenyl
polymer 72 R₅=n-hexyloxy, R₆═R₈═H, R₇=2-ethylhexyl
polymer 73 R₅═H, R₆=phenyl, R₇═R₈=3,7-dimethyloctyl 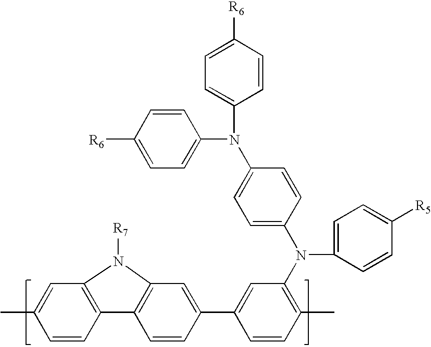
polymer 74 R₅=n-hexyl, R₆═H, R₇=(4-t-butyl)phenyl
polymer 75 R₅=n-hexyl, R₆═H, R₇=2-ethylhexyl
polymer 76 R₅═R₇=4-(bis(4-methylphenyl)amino)phenyl, R₆=n-hexyl
polymer 77 R₅═R₆═H, R₇=2-ethylhexyl
polymer 78 R₅=n-hexyloxy, R₆═H, R₇=t-butyl
polymer 79 R₅═R₆=trifluoromethyl, R₇=n-hexyl 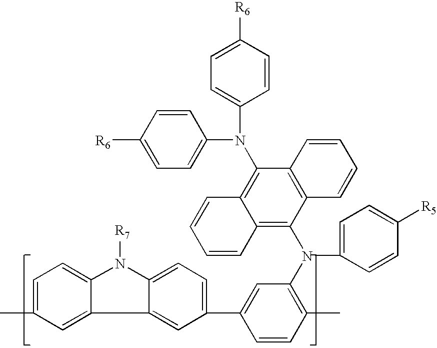
polymer 80 R₅=n-hexyl, R₆═H, R₇=(4-t-butyl)phenyl
polymer 81 R₅═R₆═H, R₇=3,7-dimethyloctyl
polymer 82 R₅═R₆=n-hexyl, R₇=2-ethylhexyl
polymer 83 R₅=n-hexyloxy, R₆═H, R₇=t-butyl 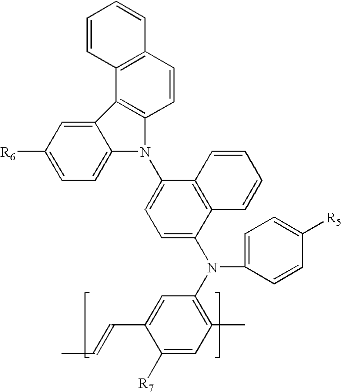
polymer 84 R₅═R₆═R₇=n-hexyl
polymer 85 R₅═R₆=n-hexyloxy, R₇═H
polymer 86 R₅═R₇═H, R₆=n-octyl
polymer 87 R₅=n-decyl, R₆=phenyl, R₇═H
polymer 88 R₅=n-hexyloxy, R₆═R₇=n-hexyl 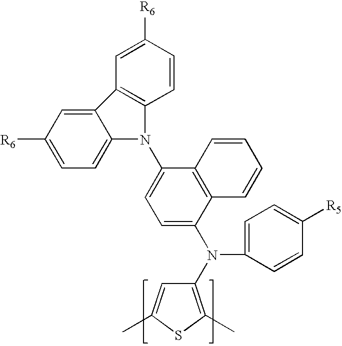
polymer 89 R₅=n-hexyl, R₆═H
polymer 90 R₅═R₆=n-hexyl
polymer 91 R₅═H, R₆=2-ethylhexyloxy.
polymer 92 R₅═H, R₆=2-ethylhexyl 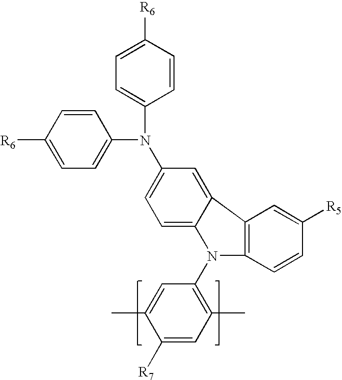
polymer 93 R₅═R₇=n-hexyl, R₆═H
polymer 94 R₅═R₆=methyl, R₇=n-decyl
polymer 95 R₅═R₆═R₇=n-hexyl
polymer 96 R₅═R₆═R₇=n-hexyloxy 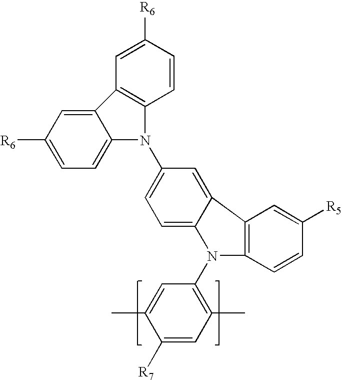
polymer 97 R₅=n-hexyl, R₆═H, R₇=(4-t-butyl)phenyl
polymer 98 R₅═H, R₆=n-hexyl, R₇=2-ethylhexyl
polymer 99 R₅═R₆═H, R₇=4-decylphenyl)
polymer 100 R₅═R₆=n-hexyl, R₇=2-ethylhexyloxy 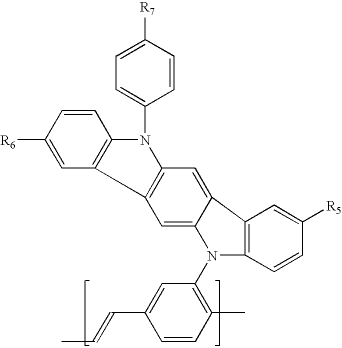
polymer 101 R₅=n-hexyl, R₆═H, R₇=(4-t-butyl)phenyl
polymer 102 R₅═R₆=n-hexyl, R₇=2-ethylhexyl
polymer 103 R₅═R₇=n-hexyloxy, R₆═H 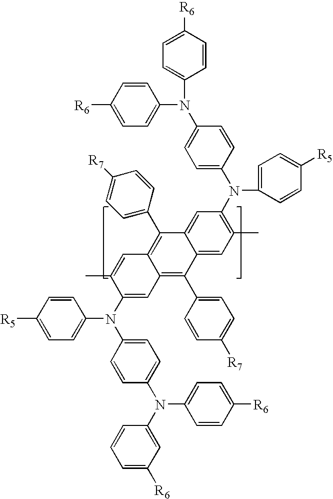
polymer 104 R₅═R₆═R₇=n-hexyl
polymer 105 R₅═R₆═H, R₇=4-octylphenyl
polymer 106 R₅═R₆=methyl, R₇=2-ethylhexyloxy
polymer 107 R₅═R₆═R₇=n-hexyloxy 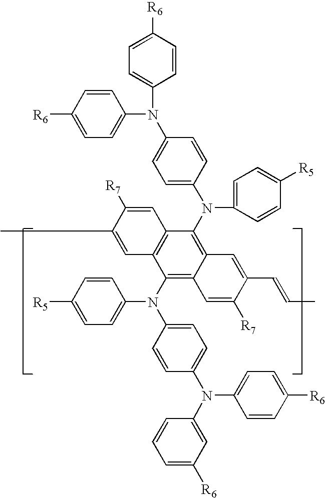
polymer 108 R₅═R₆=3,7-dimethyloctyl, R₇═H
polymer 109 R₅═H, R₆=4-t-butylphenyl, R₆=2-ethylhexyl
polymer 110 R₅═R6=n-hexyloxy, R₇═H
polymer 111 R₅=n-hexyloxy, R₆=2-ethylhexyl, R₇=t-butyl 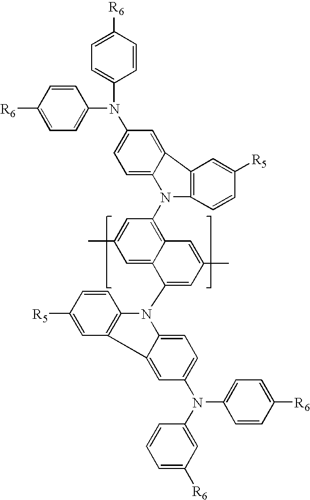
polymer 112 R₅═R₆=n-hexyl
polymer 113 R₅═R₆=n-hexyloxy
polymer 114 R₅═H, R₆=n-octyl
polymer 115 R₅=methyl, R₆=4-hexylphenyl 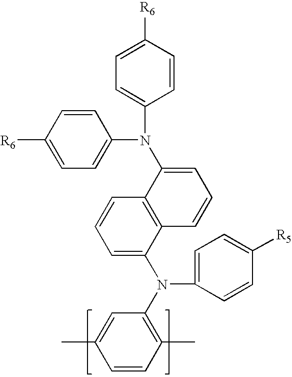
polymer 116 R₅═H, R₆=n-hexyloxy
polymer 117 R₅=n-hexyl R₆=4-(t-butylphenyl)
polymer 118 R₅═R₆=2-ethylhexyl 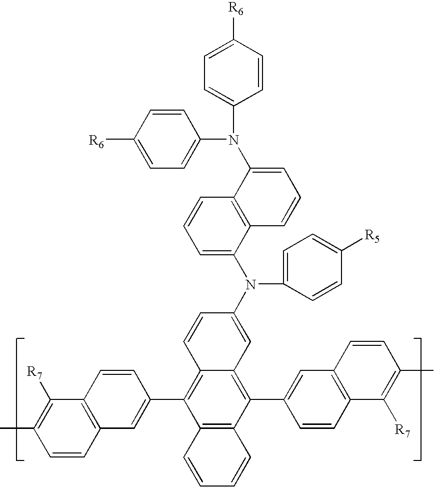
polymer 119 R₅=n-hexyl, R₆═H, R₇=2-ethylhexyl
polymer 120 R₅=methyl, R₆=n-hexyloxy, R₇=4-(t-butylphenyl)
polymer 121 R₅═R₆=n-hexyl, R₇═H
polymer 122 R₅═H, R₆=n-hexyl, R₇=3,7-dimethyloctyl 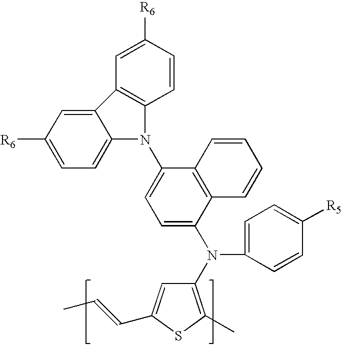
polymer 123 R₅═H, R₆=n-hexyl
polymer 124 R₅═R₆=n-hexyloxy
polymer 125 R₅=4-(bisphenylamino)phenyl, R₆=2-ethylhexyl
polymer 126 R₅=n-decyloxy, R₆═H 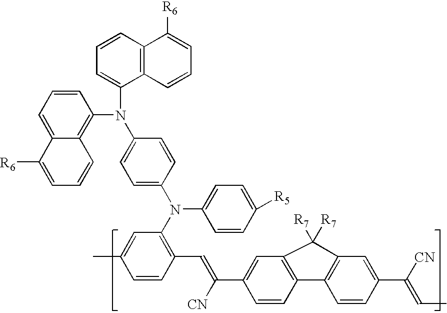
polymer 127 R₅═R₆═R₇=n-hexyl
polymer 128 R₅=methyl, R₆=n-hexyloxy, R₇=n-hexyl
polymer 129 R₅═H, R₆=n-octyl, R₇=4-(bis(4-methylphenyl)amino)phenyl
polymer 130 R₅═R₆═H, R₇=3,7-dimethyloctyl 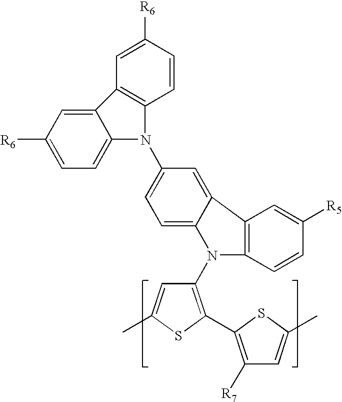
polymer 131 R₅═R₇═H, R₆=n-hexyl
polymer 132 R₅═R₇=4-(bis(4-methylphenyl)amino)phenyl, R₆=n-decyl
polymer 133 R₅═R₆=n-hexyl, R₇═H
polymer 134 R₅═H, R₆=n-hexyloxy, R₇=n-hexyl 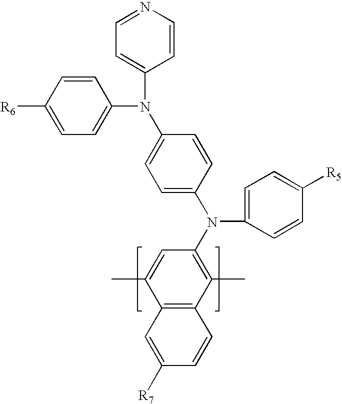
polymer 135 R₅=6=R₇=n-hexyl
polymer 136 R₅═R₇=4-(bis(4-hexylphenyl)amino)phenyl, R₆═H
polymer 137 R₅═R₆=n-hexyl, R₇=2-ethylhexyloxy
polymer 138 R₅═R₇═H, R₆=n-hexyloxy 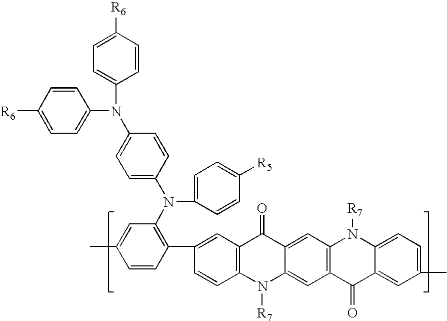
polymer 139 R₅═H, R₆=n-hexyl, R₇=(4-t-butyl)phenyl
polymer 140 R₅═R₆=2-ethylhexyl, R₇=4-(bis(4-methylphenyl)amino)phenyl
polymer 141 R₅═R₆═R₇=2-ethylhexyl
polymer 142 R₅═R₆=n-hexyloxy, R₇=t-butyl
polymer 143 R₅═R₆=4-hexylphenyl, R₇=trifluoromethyl 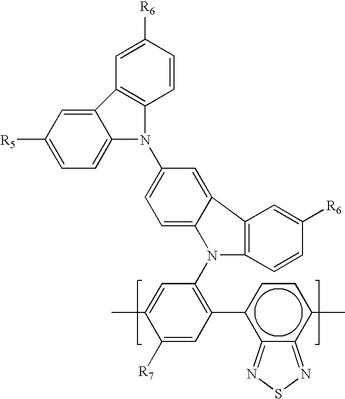
polymer 144 R₅=n-hexyl, R₆═H, R₇=(4-t-butyl)phenyl
polymer 145 R₅═R₆═R₇=n-hexyloxy
polymer 146 R₅═R₆=n-hexyl, R₇=2-ethylhexyl
polymer 147 R₅=n-hexyloxy, R₆═R₇=2-ethylhexyl
polymer 148 R₅═R₆═R₇=n-hexyl 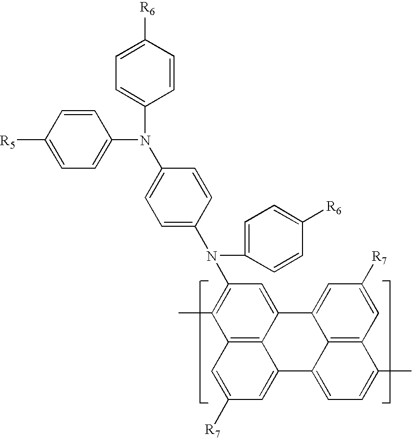
polymer 149 R₅=n-hexyl, R₆═H, R₇=(4-decyl)phenyl
polymer 150 R₅═R₆═R₇=n-hexyl
polymer 151 R₅═R₆=n-hexyl, R₇=2-ethylhexyloxy
polymer 152 R₅=n-hexyloxy, R₆=2-ethylhexyl, R₇═H
polymer 153 R₅═R₆=n-octyl, R₇=trifluoromethyl 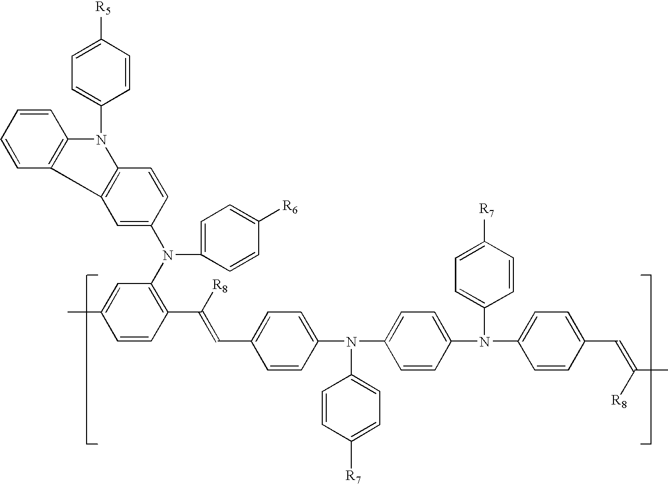
polymer 154 R₅═R₆=n-hexyl, R₇=t-butyl, R₈═H
polymer 155 R₅=2-ethylhexyl, R₆=n-hexyl, R₇=4-t-butylphenyl, R₈═CN
polymer 156 R₅═R₆=n-hexyloxy, R₇=t-butyl, R₈=phenyl
polymer 157 R₅=n-hexyl, R₆═H, R₇=(4-diphenylamino)phenyl, R₈═CN 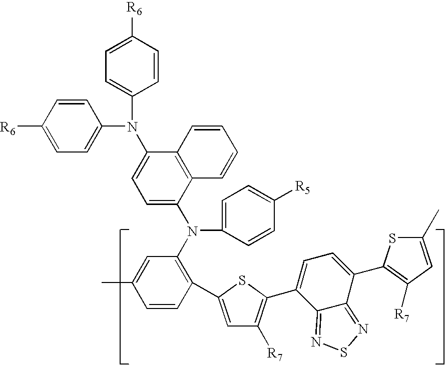
polymer 158 R₅═R₆═R₇=n-hexyl
polymer 159 R₅═R₆=2-ethylhexyloxy, R₇═H
polymer 160 R₅=n-hexyoxy, R₆=n-hexyl, R₇═H
polymer 161 R₅=n-hexyl, R₆═H, R₇=(4-diphenylamino)phenyl 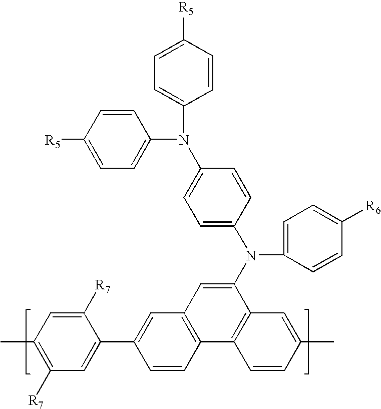
polymer 162 R₅═R₆═R₇=n-hexyl
polymer 163 R₅=2-ethylhexyl, R₆=n-hexyloxy, R₇═H
polymer 164 R₅═R₆═R₇=n-hexyloxy
polymer 165 R₅=n-hexyl, R₆═H, R₇=(4-diphenylamino)phenyl 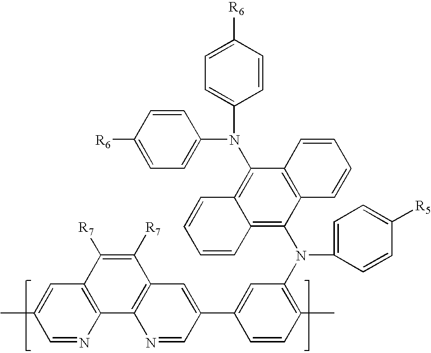
polymer 166 R₅═R₆=n-hexyl, R₇=phenyl
polymer 167 R₅=2-ethylhexyl, R₆=n-hexyloxy, R₇═H
polymer 168 R₅═R₆═R₇=3,7-dimethyloctyloxy
polymer 169 R₅=methyl, R₆=3,7-dimethyloctyl, R₇=(4-diphenylamino)phenyl 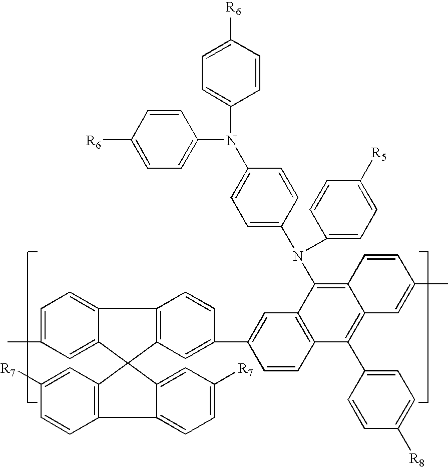
polymer 170 R₅═R₆=n-hexyl, R₇═H, R₈=2-ethylhexyloxy
polymer 171 R₅═R₆=n-hexyloxy, R₇=2-ethylhexyloxy, R₈═H
polymer 172 R₅═R₇═H, R₆=2-ethylhexyl, R₈=4-(bis(4-methylphenyl)amino)phenyl
polymer 173 R₅=n-hexyl, R₆═R₈=2-ethylhexyl 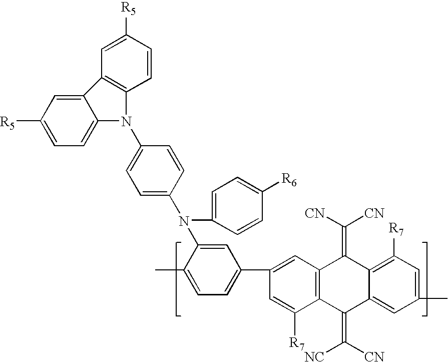
polymer 174 R₅═R₇=n-hexyloxy, R₆═H
polymer 175 R₅═R₆=n-hexyl, R₇=3,7-dimethyloctyloxy
polymer 176 R₅=n-octyl, R₆=methyl, R₇=4-hexylphenyl
polymer 177 R₅=trifluoromethyl, R₆=t-butylphenyl, R₇=2-ethylhexyl 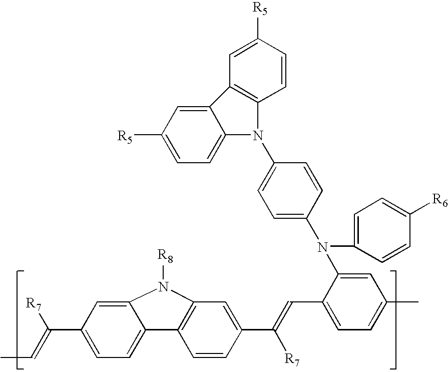
polymer 178 R₅═R₆ n-hexyl, R₇=phenyl, R₈=2-ethylhexyl
polymer 179 R₅=n-hexyl, R₆═H, R₇═CN, R₈=3,7-dimethyloctyloxy
polymer 180 R₅=n-hexyloxy, R₆═R₈=3,7-dirnethyloctyl, R₇═H
polymer 181 R₅=2-ethylhexyl, R₆=n-hexyl, R₇═H, R₈=4-t-butylphenyl 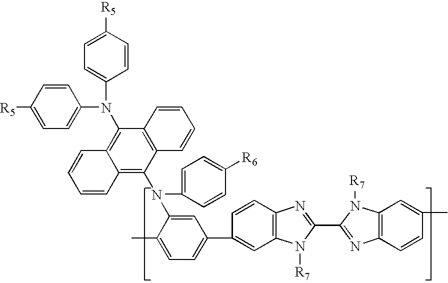
polymer 182 R₅═R₆═R₇=n-hexyl
polymer 183 R₅=n-decyl, R₆═H, R₇=(4-diphenylamino)phenyl
polymer 184 R₅═R₆=n-hexyloxy, R₇=4-t-butylphenyl
polymer 185 R₅=4-t-butylphenyl, R₆=methyl, R₇=2-ethylhexyl 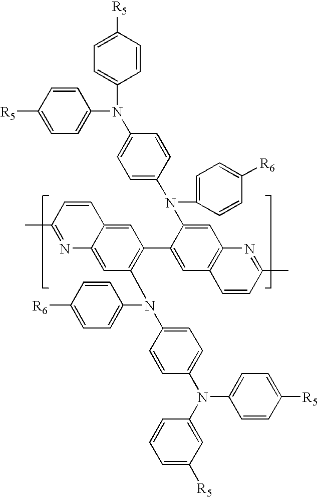
polymer 186 R₅═R₆=n-hexyl
polymer 187 R₅═R=n-hexyloxy
polymer 188 R₅=2-ethylhexyl R₆═H
polymer 189 R₅=4-hexyloxyphenyl, R₆=methyl 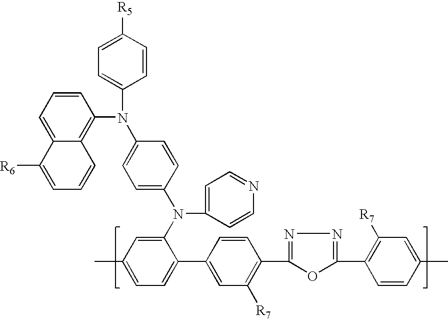
polymer 190 R₅=n-hexyl, R₆═H, R₇=(4-diphenylamino)phenyl
polymer 191 R₅═R₇=n-hexyloxy, R₆═H
polymer 192 R₅═R₆═R₇=n-hexyl 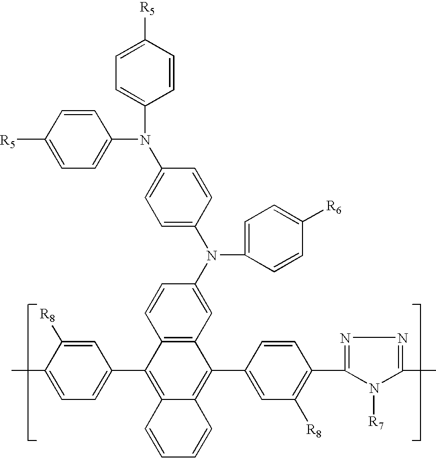
polymer 193 R₅═R₇=2-ethylhexyl, R₆═H, R₈=2-ethylhexyloxy
polymer 194 R₅═R₆=n-hexyloxy, R₇=3,7-dimethyloctyloxy, R₈═H
polymer 195 R₅=methyl, R₆=(4-diphenylamino)pheny,1 R₇═R₈₌3,7-dimethyloctyl 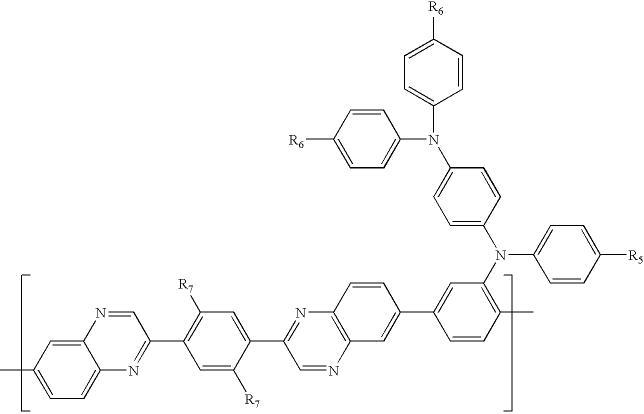
polymer 196 R₅═R₆=n-hexyl, R₇=t-butyl
polymer 197 R₅═R₆=2-ethylhexyl, R₇═H
polymer 198 R₅═R₇=n-octyloxy, R₆=methyl,
polymer 199 R₅=n-hexyl, R₆═H, R₇=(4-diphenylamino)phenyl 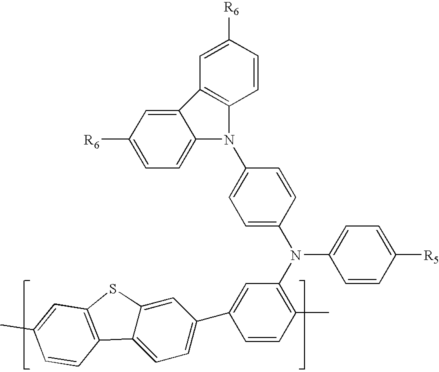
polymer 200 R₅═R₆=n-hexyl
polymer 201 R₅═R₆=2-ethylhexyloxy
polymer 202 R₅=n-hexyloxy, R₆=(4-diphenylamino)phenyl
polymer 203 R₅═R₆=4-hexylphenyl 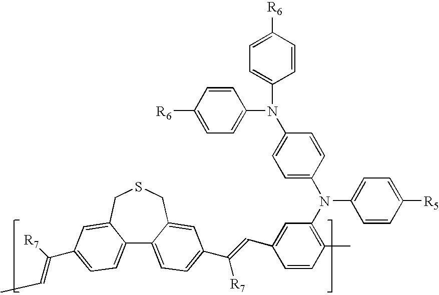
polymer 204 R₅═R₆=n-hexyl, R₇═H
polymer 205 R₅=methyl, R₆=2-ethylhexyloxy, R₇=phenyl
polymer 206 R₅═R₆=n-hexyloxy, R₇═CN
polymer 207 R₅=(4-diphenylamino)phenyl, R₆=4-hexylphenyl, R₇═CN 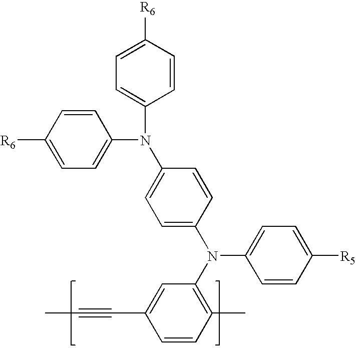
polymer 208 R₅═R₆=n-hexyl
polymer 209 R₅=4-(bis(4-methylphenyl)amino)phenyl, R₆=hexyloxy
polymer 210 R₅═R₆=n-hexyloxy 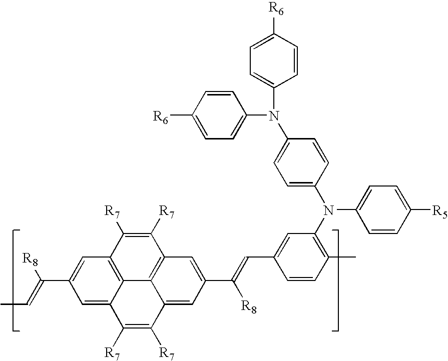
polymer 211 R₅═R₆=n-hexyloxy, R₇=2-ethylhexyl, R₈=phenyl
polymer 212 R₅═R₆=n-hexyl, R₇=2-ethylhexyloxy, R₈═H
polymer 213 R₅=4-hexylphenyl, R₆=methyl, R₇=n-octyl, R₈═CN 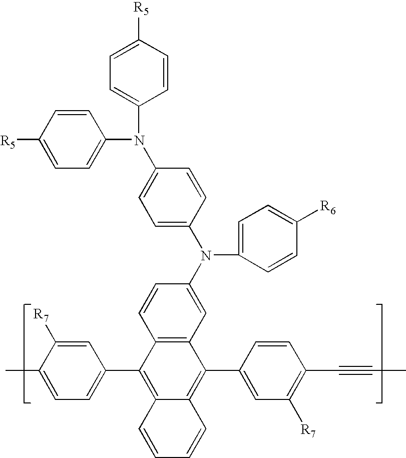
polymer 214 R₅═R₆═R₇=n-hexyloxy
polymer 215 R₅=n-hexyloxy, R₆=2-ethylhexyl, R₇═H
polymer 216 R₅═R₆═R₇=n-hexyl 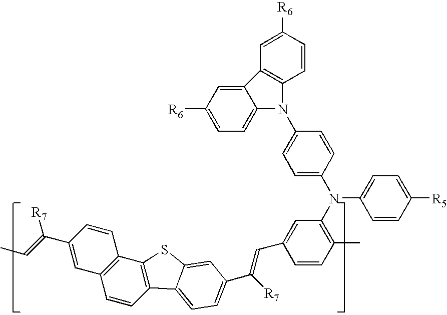
polymer 217 R₅═R₆=2-ethylhexyloxy, R₇═H
polymer 218 R₅=methyl, R₆=n-hexyl, R₇═CN
polymer 219 R₅=(4-diphenylamino)phenyl, R₆=2-ethylhexyl, R₇=phenyl 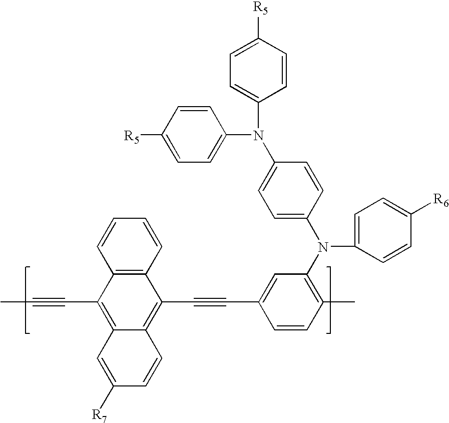
polymer 220 R₅═R₆═R₇=n-hexyl
polymer 221 R₅═R₆═R₇=hexyloxy
polymer 222 R₅═R₇=2-ethylhexyl, R₆=di-tolylamino

The specific molecular structures can be the combination of any of the above drawn structures.

The conjugated polymers comprising arylamine structure (I) can be synthesized using known methods. The polymerization method and the molecular weights of the resulting polymers used in the present invention are not necessary to be particularly restricted. The molecular weights of the polymers are at least 1000, and preferably at least 2000. The polymers may be prepared by condensation polymerizations, such as coupling reactions including Pd-catalyzed Suzuki coupling, Stille coupling or Heck coupling, or Ni-mediated Yamamoto coupling, or by other condensation methods such as Wittig reaction, or Horn er-Emmons reaction, or Knoevenagel reaction, or dehalogenation of dibenzyl halides. According to the present invention, the above mentioned polymers were prepared by a Horner-Emmons reaction between an aromatic dicarboxyaldehyde and a diphosphate, or a Knoevenagel reaction using an aromatic dicarboxyaldehyde and a dicyano compound in the presence of a strong base such as potassium t-butoxide or sodium hydride.

Suzuki coupling reaction was first reported by Suzuki et al on the coupling of aromatic boronic acid derivatives with aromatic halides (Suzuki, A. et al Synthetic Comm. 1981, 11(7), 513). Since then, this reaction has been widely used to prepared polymers for various applications (Ranger, M. et al Macromolecules 1997, 30, 7686). The reaction involves the use of a palladium-based catalyst such as a soluble Pd compound either in the state of Pd (II) or Pd (0), a base such as an aqueous inorganic alkaline carbonate or bicarbonate, and a solvent for the reactants and/or product. The preferred Pd catalyst is a Pd (0) complex such as Pd(PPh₃)₄ or a Pd (II) salt such as Pd(PPh₃)₂Cl₂ or Pd(OAc)₂ with a tertiary phosphine ligand, and used in the range of 0.01 -10 mol % based on the functional groups of the reactants. Polar solvents such as THF and non-polar solvents toluene can be used however, the non-polar solvent is believed to slow down the reaction. Modified processes were reported to prepare conjugated polymers for EL devices from the Suzuki coupling of aromatic halides and aromatic boron derivatives (Inbasekaran, M. et al U.S. Pat. No. 5,777,070 (1998); Towns, C. R. et al. PCT WO00/53656, 2000). A variation of the Suzuki coupling reaction replaces the aromatic halide with an aromatic trifluoromethanesulfonate (triflate) (Ritter, K. Synthesis, 1993, 735). Aromatic triflates are readily prepared from the corresponding phenol derivatives. The advantages of using aromatic triflates are that the phenol derivatives are easily accessible and can be protected/deprotected during complex synthesis. For example, aromatic halides normally would react under various coupling conditions to generate unwanted by-product and lead to much more complicated synthetic schemes. However, phenol derivatives can be easily protected by various protecting groups that would not interfere with functional group transformation and be deprotected to generate back the phenol group which then can be converted to triflates. The diboron derivatives can be prepared from the corresponding dihalide or ditriflate.

The synthetic schemes of the polymers according to the present invention are illustrated in Schemes 1-3.

The process of the invention provides conjugated polymers particularly useful for an optical device. The optical device may comprise a luminescent device such as an EL device in which the polymers of the present invention is deposited between a cathode and an anode. The polymers can be deposited as thin film by vapor deposition or thermal transfer method or from a solution by spin-coating, spray-coating, dip-coating, roller-coating, or ink jet delivery. The thin film may be supported by substrate directly, preferably a transparent substrate, or supported by the substrate indirectly where there is one or more inter layers between the substrate and thin film. The thin film can be used as emitting layer or charge carrier transporting layer.

General EL Device Architecture:

The present invention can be employed in most organic EL device configurations. These include very simple structures including a single anode and cathode to more complex devices, such as passive matrix displays comprised of orthogonal arrays of anodes and cathodes to form pixels, and active-matrix displays where each pixel is controlled independently, for example, with thin film transistors (TFTs).

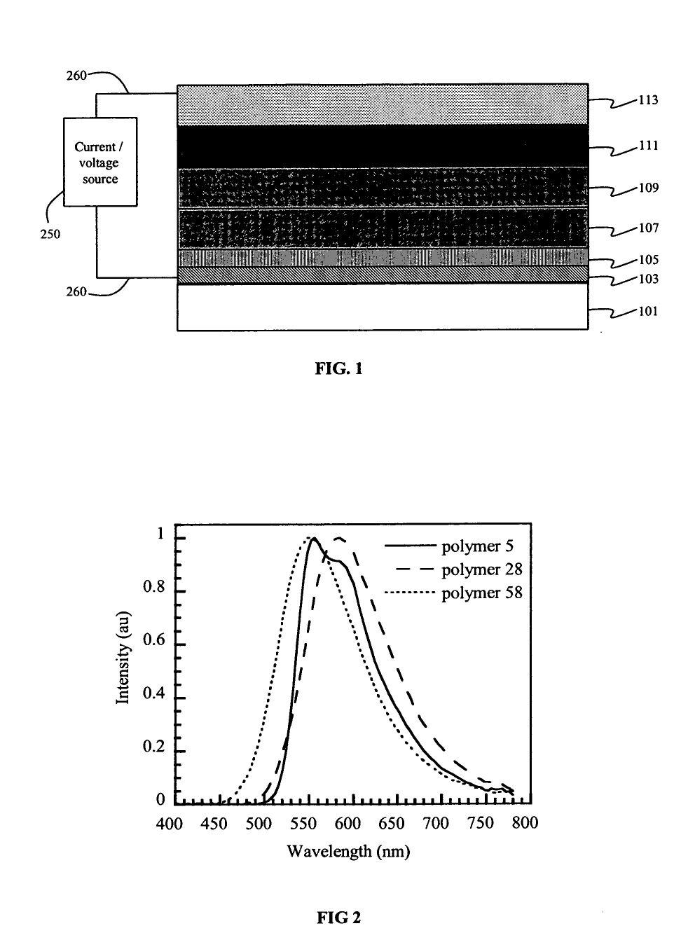

There are numerous configurations of the organic layers wherein the present invention can be successfully practiced. A typical structure is shown in FIG. 1 and includes a substrate 101, an anode 103, a hole-injecting layer 105, a hole-transporting layer 107, a light-emitting layer 109, an electron-transporting layer 111, and a cathode 113. These layers are described in detail below. This figure is for illustration only and the individual layer thickness is not scaled according to the actual thickness. Note that the substrate 101 may alternatively be located adjacent to the cathode 113, or the substrate may actually constitute the anode 103 or cathode 113. The organic layers between the anode 103 and cathode 113 are conveniently referred to as the organic EL element.

The anode 103 and cathode 113 of the OLED are connected to a voltage/current source 250 through electrical conductors 260. The OLED is operated by applying a potential between the anode 103 and cathode 113 such that the anode 103 is at a more positive potential than the cathode 113. Holes are injected into the organic EL element from the anode 103 and electrons are injected into the organic EL element at the anode 103. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate:

The OLED device of this invention is typically provided over a supporting substrate 101 where either the cathode 113 or anode 103 can be in contact with the substrate 101. The electrode in contact with the substrate 101 is conveniently referred to as the bottom electrode. Conventionally, the bottom electrode is the anode 103, but this invention is not limited to that configuration. The substrate 101 can either be light transmissive or opaque, depending on the intended direction of light emission. The light transmissive property is desirable for viewing the EL emission through the substrate 101. Transparent glass or plastic is commonly employed in such cases. The substrate 101 may be a complex structure comprising multiple layers of materials. This is typically the case for active matrix substrates wherein TFTs are provided below the EL layers. It is still necessary that the substrate, at least in the emissive pixilated areas, be comprised of largely transparent materials such as glass or polymers. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, silicon, ceramics, and circuit board materials. Again, the substrate may be a complex structure comprising multiple layers of materials such as found in active matrix TFT designs. Of course it is necessary to provide in these device configurations a light-transparent top electrode.

Anode:

When EL emission is viewed through anode 103, the anode 103 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 103. Anode 103 can be modified with plasma-deposited fluorocarbons as disclosed in EP 0914025. For applications where EL emission is viewed only through the cathode electrode, the transmissive characteristics of anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injection Layer (HIL):

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer 107. Suitable materials for use in the hole-injecting layer 105 include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1.

Hole-Transporting Layer (HTL)

The hole-transporting layer 107 of the organic EL device in general contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No.3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural formula (A). 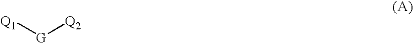
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 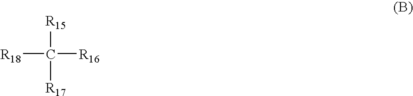
wherein:

R₁₅ and R₁₆ each independently represents a hydrogen atom, an aryl group, or an alkyl group or R₁₅ and R₁₆ together represent the atoms completing a cycloalkyl group; and
R₁₇ and R₁₈ each independently represents an aryl group, which is in turn substituted with a diaryl substituted amino group, as indicated by structural formula (C): 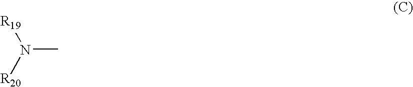
   wherein R₁₉ and R₂₀ are independently selected aryl groups. In one embodiment, at least one of R₁₉ or R₂₀ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D): 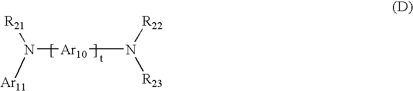
wherein
each Ar₁₀ is an independently selected arylene group, such as a phenylene or anthracene moiety,
t is an integer of from 1 to 4, and
Ar₁₁, R₂₁, R₂₂, and R₂₃ are independently selected aryl groups.

In a typical embodiment, at least one of Ar₄, R₂₁, R₂₂, and R₂₃ is a polycyclic fused ring structure, e.g., a naphthalene

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—eg, cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolyiamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N ′-tetra-1-naphthyl-4,4′-diaminobiphenyl
N,N,N′,N ′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis{N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting/hole injection materials can be used such as poly(N-vinylcarbazole) (PVK), polythiophenes, polypyrrole, polyaniline (Yang, Y. et al. Appl. Phys. Lett. 1994, 64, 1245) and copolymers such as poly(3,4-ethylenedioxythiophene)/poly(4-styrenesulfonate) also called PEDOT/PSS(Groenendaal, L. B. et al. Adv. Mater. 2000, 12, 481).

Light-Emitting Layer (LEL)

As more fully described in U.S. Pat. Nos. 4,769,292 and 5,935,721, the light-emitting layer (LEL) 109 of the organic EL element includes a luminescent or fluorescent material where electroluminescence is produced as a result of electron-hole pair recombination in this region. The light-emitting layer 109 can include a single material including both small molecules and polymers. For small molecules, LEL more commonly consists of a host material doped with a guest compound or compounds where light emission comes primarily from the dopant and can be of any color. The host materials in the light-emitting layer 109 can be an electron-transporting material, as defined below, a hole-transporting material, as defined above, or another material or combination of materials that support hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Simultaneously, the color of the EL devices can be tuned using dopants of different emission wavelengths. By using a mixture of dopants, EL color characteristics of the combined spectra of the individual dopant are produced. This dopant scheme has been described in considerable detail for EL devices in U.S. Pat. No. 4,769,292 for fluorescent dyes. Dopants are typically coated as 0.01 to 10% by weight into the host material. Polymeric materials such as polyfluorenes and poly(arylene vinylenes) (e.g., poly(p-phenylenevinylene), PPV) can also be used as the host material. In this case, small molecule dopants can be molecularly dispersed into the polymeric host, or the dopant could be added by copolymerizing a minor constituent into the host polymer.

An important relationship for choosing a dye as a dopant is a comparison of the bandgap potential which is defined as the energy difference between the highest occupied molecular orbital (HOMO) and the lowest unoccupied molecular orbital (LUMO) of the molecule. For efficient energy transfer from the host to the dopant molecule, a necessary condition is that the band gap of the dopant is smaller than that of the host material. For phosphorescent emitters it is also important that the host triplet energy level of the host be high enough to enable energy transfer from host to dopant.

For small molecules, host and emitting molecules known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721, and 6,020,078.

For example, small molecule metal complexes of 8-hydroxyquinoline and similar derivatives (Formula E) constitute one class of useful host compounds capable of supporting electroluminescence, and are particularly suitable for light emission of wavelengths longer than 500 nm, e.g., green, yellow, orange, and red. 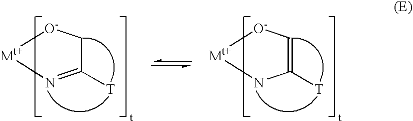
wherein:
M represents a metal;
t is an integer of from 1 to 4; and
T independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

T completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo {f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Derivatives of 9,10-di-(2-naphthyl)anthracene (Formula F) constitute one class of useful hosts capable of supporting electroluminescence, and are particularly suitable for light emission of wavelengths longer than 400 nm, e.g., blue, green, yellow, orange or red. 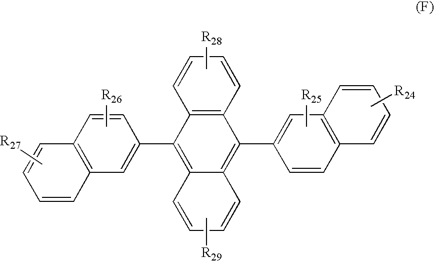
wherein: R₂₄, R₂₅, R₂₆, R₂₇, R₂₈, and R₂₉ represent one or more substituents on each ring where each substituent is individually selected from the following groups:

Group 1: hydrogen, or alkyl of from 1 to 24 carbon atoms;

Group 2: arylof from 5 to 20 carbon atoms;

Group 3: carbon atoms from 4 to 24 necessary to complete a fused aromatic ring of anthracenyl; pyrenyl, or perylenyl;

Group 4: heteroarylof from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

Illustrative examples include 9,10-di-(2-naphthyl)anthracene and 2-t-butyl-9,10-di-(2-naphthyl)anthracene. Other anthracene derivatives can be useful as a host in the LEL, including derivatives of 9,10-bis[4-(2,2-diphenylethenyl)phenyl]anthracene.

Distyrylarylene derivatives are also useful hosts, as described in U.S. Pat. No.5,121,029. Carbazole derivatives are particularly useful hosts for phosphorescent emitters.

Polymers incorporating the above small molecule moieties as represented by formulas (E), and (F) are useful host materials. Examples of 9,10-di-(2-naphthyl)anthracene-containing polymers are disclosed U.S. Pat. No. 6,361,887.

Useful fluorescent dopants (FD) include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds. Useful phosphorescent dopants (PD) include but are not limited to organometallic complexes of transition metals of iridium, platinum, palladium, or osmium. Illustrative examples of useful dopants include, but are not limited to, the following: 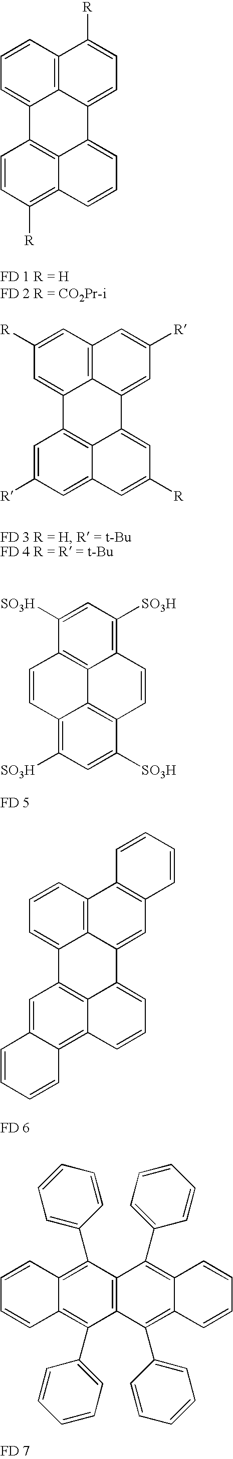 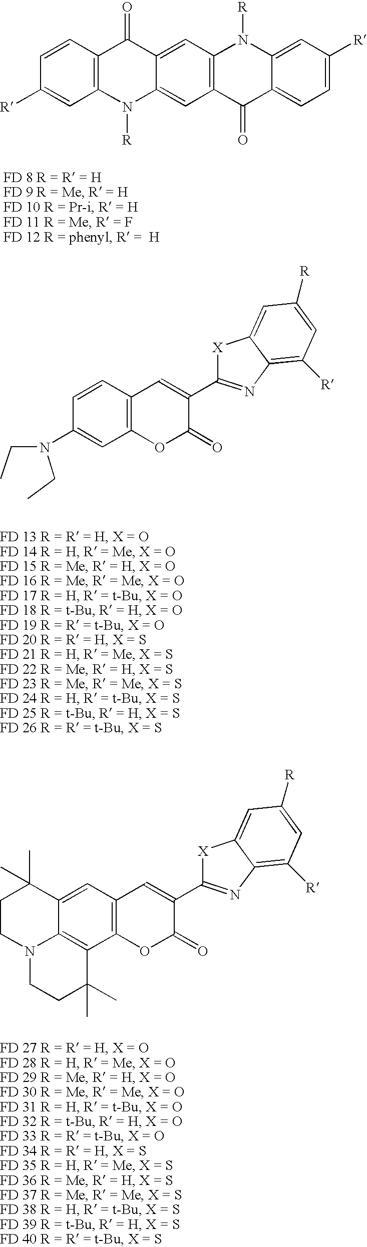 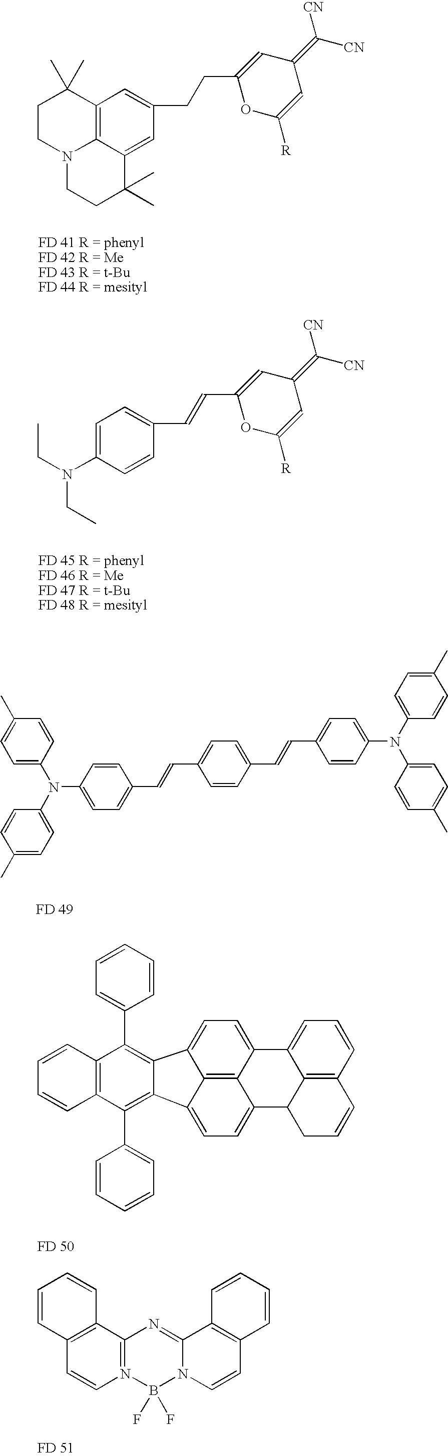 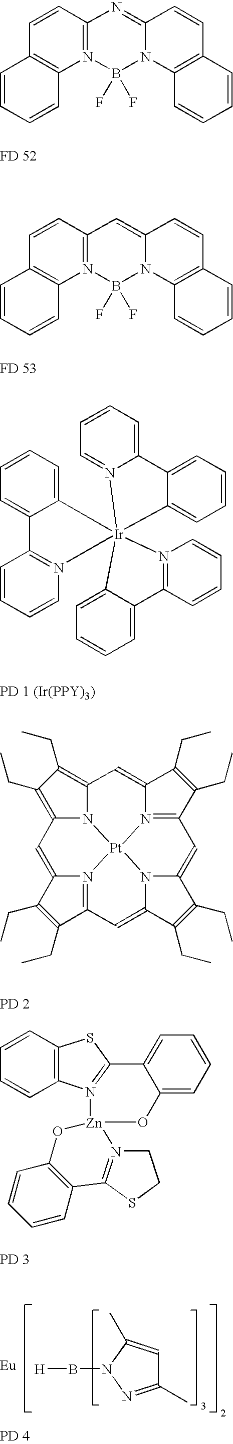
Electron-Transporting Layer (ETL):

Preferred thin film-forming materials for use in forming the electron-transporting layer 111 of the organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described.

Other electron-transporting materials include various butadiene derivatives as disclosed in U.S. Pat. No. 4,356,429 and various heterocyclic optical brighteners as described in U.S. Pat. No. 4,539,507. Triazines are also known to be useful as electron transporting materials. Oxadiazole compounds including small molecules and polymers are useful electron transporting materials as described in U.S. Pat. No. 6,451,457.

Cathode

When light emission is viewed solely through the anode, the cathode 113 used in this invention can include nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. Nos. 4,885,211; 5,247,190,; 5,703,436; 5,608,287; 5,837,391; 5,677,572; 5,776,622; 5,776,623; 5,714,838; 5,969,474; 5,739,545; 5,981,306; 6,137,223; 6,140,763; 6,172,459; 6,278,236; 6,284,393, JP 3,234,963 and EP 1 076 368,. Cathode materials are typically deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Other Useful Organic Layers and Device Architecture

In some instances, layers 109 and 111 can optionally be collapsed into a single layer that serves the function of supporting both light emission and electron transportation or layers 107 and 109 can optionally be collapsed into a single layer that serves the function of supporting both light emission and hole transportation. Alternatively, layers 107, 109 and 111 can optionally be collapsed into a single layer that serves the function of supporting both light emission and hole and electron transportation. This is the preferred EL device structure of this invention and is referred to as “single-layer” device.

It also known in the art that emitting dopants may be added to the hole-transporting layer, which may serve as a host. Multiple dopants may be added to one or more layers in order to create a white-emitting EL device, for example, by combining blue- and yellow-emitting materials, cyan- and red-emitting materials, or red-, green-, and blue-emitting materials. White-emitting devices are described, for example, in EP 1 187 235, EP 1 182 244, U.S. Published patent application 20020025419, U.S. Pat. Nos. 5,683,823; 5,503,910; 5,405,709, and 5,283,182.

Additional layers such as electron or hole-blocking layers as taught in the art may be employed in devices of this invention. Hole-blocking layers are commonly used to improve efficiency of phosphorescent emitter devices, for example, as in U.S. Published patent application 20020015859.

This invention may be used in so-called stacked device architecture, for example, as taught in U.S. Pat. Nos. 5,703,436 and 6,337,492.

Deposition of Organic Layers

The organic materials mentioned above can be deposited as high quality transparent thin films by various methods such as a vapor deposition or sublimation method, an electron-beam method, a sputtering method, a thermal transferring method, a molecular lamination method and a coating method such as solution casting, spin-coating or inkjet printing, with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551; 5,851,709 and 6,066,357) and inkjet method (U.S. Pat. No. 6,066,357).

Preferably, the spin-coating or inkjet printing technique is used to deposit the conjugated polymer of the invention, and only one polymer is deposited in a single layer device.

Encapsulation:

Most organic EL devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization:

Organic EL devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

### EXAMPLES

The invention and its advantages are further illustrated by the following specific examples:

### Synthesis of Monomers

The monomers to be used in the present invention to construct polymers are not necessary to be particularly restricted. Any monomers can be used as long as the polymer formed is a polymer which satisfies the formula (I). Typical synthesis is illustrated in Schemes 1-3.

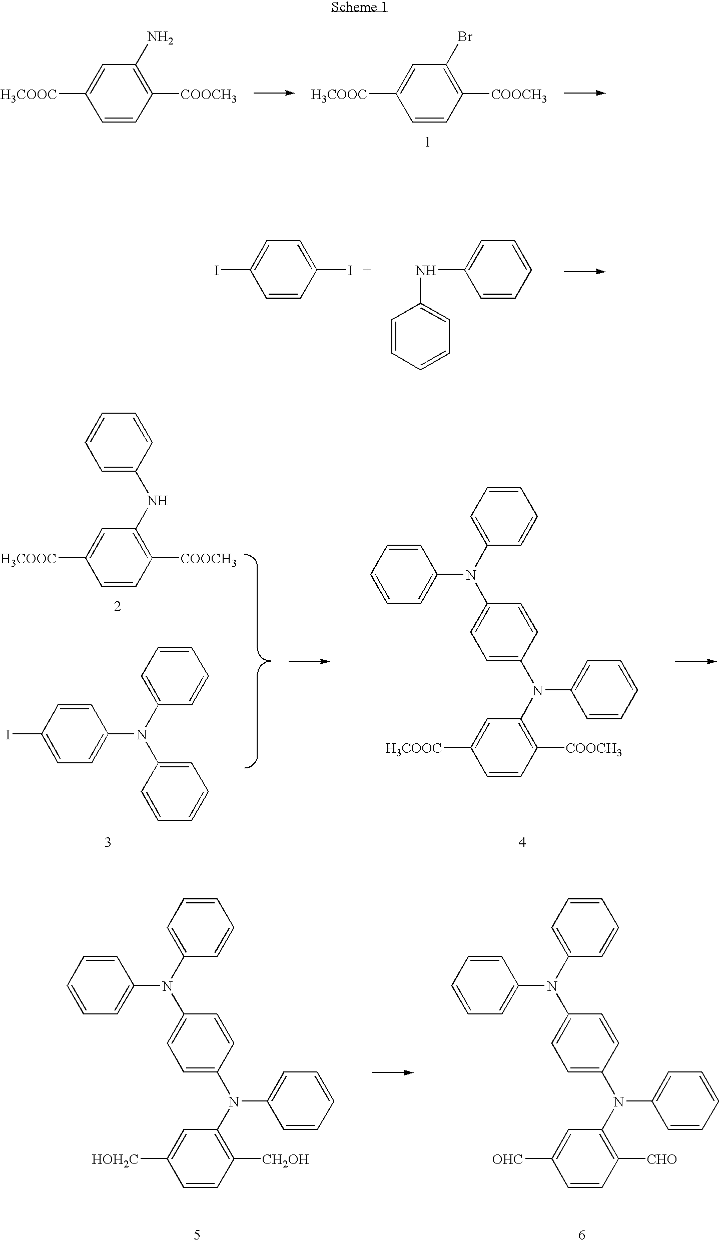

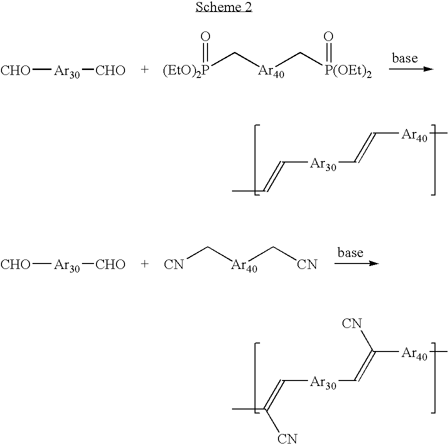

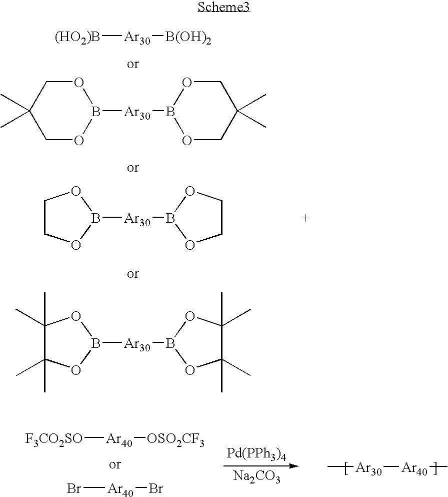

### Example 1

### Synthesis of dimethyl 2-bromo-terephthalate (compound 1)

Dimethyl 2-amino-terephthalate (10.0 g, 0.048 mol) was dissolved in 60 mL of concentrated HBr solution (50% in water) at 60° C. The red solution was cooled in an ice-bath and a microcrystalline suspension was obtained. To this suspension was added 2.5 M NaNO₂ solution (21 mL, 0.052 mol) under vigorous stirring. The resulting yellow diazonium compound was transferred to a cooled additional funnel (−5° C.) and added to a cooled solution of CuBr (9.1 g, 0.064 mol) in 25 mL of concentrated HBr solution. A defoaming agent n-butanol was used to prevent excessive foaming. After the addition was complete, the reaction was heated to 70° C. until no further nitrogen evolved. The reaction was cooled, and was extracted with ether. The organic phase was washed with water and dried over MgSO₄. The crude product was obtained as gray black solid and was purified by recryllization from heptane to give 6.6 g of pure product as white solid at 51% yield. ¹H NMR (CDCl₃) δ (ppm): 3.95 (s, 6 H), 7.82 (d, J=8.1 Hz, 1 H), 8.01 (dd, J₁ =8.1 Hz, J₂=1.5 Hz, 1 H), 8.32 (d, J=1.5 Hz, 1 H). ¹³C NMR (CDCl₃) δ (ppm): 52.64, 52.71, 121.36, 128.01, 130.94, 133.60, 135.09, 135.99, 164.89, 166.02. Mp 48-50° C. FD-MS: m/z 273 (M⁺).

### Example 2

### Synthesis of dimethyl 2-phenylamino-terephthalate (compound 2)

Dimethyl 2-bromo-terephthalate (10.0 g, 0.037 mol), aniline (17.0 g, 0.18 mol), potassium phosphate (11.7 g, 0.055 mol), and Pd₂(dba)₃ (0.67 g, 0.73 mmol) were mixed in 100 mL of anhydrous toluene. The mixture was bubbled with nitrogen for 10 min. and tri t-butyl phosphine (0.12 g, 0.58 mmol) was added. The reaction was heated to reflux overnight. The reaction was cooled down and extracted with ether. The combined organic phase was dried over MgSO₄ and solvent was removed. The crude product was obtained as dark brown oil. The crude product was purified by column on silica gel using 10/90 methylene chloride/heptane as an eluent to obtain yellow solid which was further recrystallized in heptane to give 6.0 g of pure product as orange crystals at 58% yield. ¹H NMR (CDCl₃) δ (ppm): 3.87 (s, 3 H), 3.93 (s, 3 H), 7.24-7.36 (m, 6 H), 7.91-8.03 (m, 2 H), 9.50 (s, br, 1H). ¹³C NMR (CDCl₃) δ (ppm): 52.06, 52.34, 114.83, 115.16, 117.24, 122.51, 124.01, 129.54, 131.75, 134.85, 140.16, 147.74, 166.54, 168.36. Mp 85-87° C. FD-MS: m/z 285 (M⁺).

### Example 3

### Synthesis of 4-diphenylamino-iodobenzene (compound 3)

Diphenyl amine (21.0 g, 0.12 mol), 1,4-diiodobenzene (49.1 g, 0.15 mol), potassium carbonate (51.4 g, 0.37 mol), copper bronze (15.6 g, 0.25 mol), and crown-18-6 (3.1 g, 15 wt % to diphenyl amine) were mixed in 200 mL of o-dichlorobenzene and the reaction was heated to reflux overnight. The reaction was cooled down and the solid was filtered off and washed with methylene chloride. The filtrate was concentrated and cooled in dry ice. 1,4-Diiodobenzene crashed out upon cooling and was filtered off. The process was repeated until most of 1,4-diiodobenzene was removed from crude product. The crude product was then purified by column chromatography on silica gel using heptane as an eluent to give 20.1 g of pure product as white solid at 44% yield. ¹H NMR (CDCl₃) δ (ppm): 6.82 (d, J=8.8 Hz, 2 H), 7.00-7.27 (m, 10 H), 7.48 (d, J=8.8 Hz). ¹³C NMR (CDCl₃) δ (ppm): 122.67, 123.30, 124.13, 124.52, 125.27, 129.17, 129.34, 138.01, 147.22, 147.69, 147.82. Mp 102-104° C. FD-MS: m/z 371 (M⁺).

### Example 4

### Synthesis of dimethyl 2-(4-diphenylaminophenyl)phenylamino-terephthalate (compound 4)

Compound 2 (5.0 g, 0.018 mol), compound 3 (7.8 g, 0.021 mol), potassium carbonate (7.3 g, 0.052 mol), copper bronze (2.2 g, 0.035 mol) and crown-18-6 (0.75 g) were mixed in 50 mL of o-dichlorobenzene and heated to reflux overnight. After cooling down, the solid was filtered off and the reaction was extracted with ether. The combined organic phase was dried over MgSO₄. The crude product was obtained as dark brown oil and was purified by column chromatography on silica gel using 25/75 methylene chloride/heptane to give 4.6 g of pure product as orange foam at 55% yield. ¹H NMR (CDCl₃) δ (ppm): 3.58 (s, 3 H), 3.95 (s, 3 H), 7.00-7.10 (m, 9 H), 7.18 (d, J=7.6 Hz, 4 H), 7.27-7.34 (m, 6H), 7.76 (d, J=8.0 Hz, 1 H), 7.62 (dd, J₁=8.0 Hz, J₂=1.4 Hz, 1 H), 7.98 (d, J=8.0 Hz, 1 H). ¹³C NMR (CDCl₃) δ (ppm): 51.88, 52.27, 122.22, 122.26, 122.34, 123.60, 124.467, 125.26, 129.06, 129.56, 131.06, 132.46, 133.89, 142.34, 142.88, 146.60, 147.36,147.63, 165.82, 167.16; Mp 139-140° C. FD-MS: m/z 528 (M⁺).

### Example 5

### Synthesis of 2-(4-diphenylaminophenyl)phenylamino-1,4-dihydroxymethylbenzene (compound 5)

Compound 4 (12.3 g, 0.023 mol) was dissolved in 100 mL of dry THF and added slowly to a cooled LiAlH₄ (1.9 g, 0.051 mol) in 100 mL of dry THF suspension. After the addition, the reaction was heated to reflux for 1 h. The reaction was cooled down and quenched with Na₂SO₄.10H₂O. The reaction was then filtered to give 10.4 g of pure product as off-white solid at 95% yield. ¹H NMR (CDCl₃) δ (ppm): 4.37 (s, 2 H), 4.56 (s, 2 H), 6.79-6.92 (m, 9 H), 6.99 (d, J=8.2 Hz, 4 H), 7.09-7.18 (m, 8 H), 7.42 (d, J=7.8 Hz, 1 H). 13C NMR (CDCl₃) δ (ppm): 62.09, 64.65, 121.12, 121.60, 122.37, 123.27, 123.62, 124.58, 125.49, 127.50, 129.16, 129.20, 129.58, 137.49, 142.02, 142.33, 142.45, 144.57, 147.64, 147.75; Mp 158-160° C. FD-MS: m/z 472 (M⁺).

### Example 6

### Synthesis of 2-(4-diphenylaminophenyl)phenylamino-1,4-diformyllbenzene (compound 6)

Compound 5 (0.89 g, 1.9 mmol) was dissolved in 15 mL of methylene chloride and pyridinium chlorochromate (PCC, 0.89 g, 4.1 mmol) was added. The reaction was stirred at room temperature for 3 h and quenched with water. The reaction was filtered through a pad of Celite and washed with methylene chloride. The filtrate was separated and the aqueous layer was extracted with methylene chloride and the organic phase was dried over MgSO₄. The crude product was obtained as black solid and was purified by column on silica gel using 30/70 ether/heptane as an eluent to give dark red foaming solid. The pure product was obtained after further recrystallization from ethanol to give 0.25 g of bright orange crystals at 17% yield. ¹H NMR (CDCl₃) δ (ppm): 6.83-7.03 (m, 14 H), 7.16-7.21 (m, 5 H), 7.59-7.62 (m, 2 H), 7.90 (d, J=7.8 Hz, 1 H). ¹³C NMR (CDCl₃) δ (ppm): 122.56, 122.88, 123.27, 124.17, 124.76, 124.87, 124.99, 129.02, 129.27, 129.75, 130.12, 135.02, 141.05, 142.81, 143.92, 147.48, 148.59, 150.96, 189.96, 191.23. Mp 159-161° C. FD-MS: m/z 468 (M⁺).

### Synthesis of Polymers

### Example 7

### General Procedure for a Horner-Emmons Reaction

Equimolar of dicarboxyaldehyde and diphosphate monomers were dissolved in anhydrous THF under nitrogen. To this solution was added 2.5 equivalent of NaH. The reaction was stirred at room temperature overnight under nitrogen. Small amount of benzaldehyde was added to endcap phosphate endgroup. The polymer was precipitated into methanol, filtered, re-dissolved in chloroform and precipitated twice more from methanol. The resulting polymer was dried under vacuum at 45° C. overnight.

### Example 8

### General Procedure for a Knoevenagel Reaction

Equimolar of dicarboxyaldehyde and dicyano monomers were dissolved in a mixed solvent of 1:1 anhydrous THF and t-butyl alcohol under nitrogen. To this solution was added catalytic amount of potassium t-butoxide. The reaction was stirred at room temperature overnight under nitrogen. The polymer was precipitated into methanol, filtered, re-dissolved in chloroform and precipitated twice more from methanol. The resulting polymer was dried under vacuum at 45° C. overnight.

### EL Device Fabrication and Performance

### Example 9

An EL device satisfying the requirements of the invention was constructed in the following manner. The organic EL medium has a single layer of the organic compound described in this invention.
a) An indium-tin-oxide (ITO) coated glass substrate was sequentially ultra-sonicated in a commercial detergent, rinsed with deionized water, degreased in toluene vapor and exposed to ultraviolet light and ozone for a few minutes.
b) An aqueous solution of PEDOT (1.3% in water, Baytron P Trial Product AI 4083 from H. C. Stark) was spin-coated onto ITO under a controlled spinning speed to obtain thickness of 500 Angstroms. The coating was baked in an oven at 110° C. for 10 min.
c) A toluene solution of a polymer (300 mg in 30 mL of solvent) was filtered through a 0.2 μm Teflon filter. The solution was then spin-coated onto PEDOT under a controlled spinning speed. The thickness of the film was between 500-1000 Angstroms. On the top of the organic thin film was deposited a cathode layer consisting of 15 angstroms of a CsF salt, followed by a 2000 angstroms of a 10:1 atomic ratio of Mg and Ag.

The above sequence completed the deposition of the EL device. The device was then hermetically packaged in a dry glove box for protection against ambient environment.

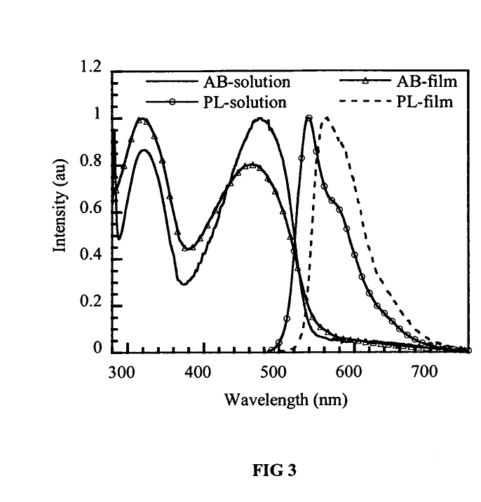

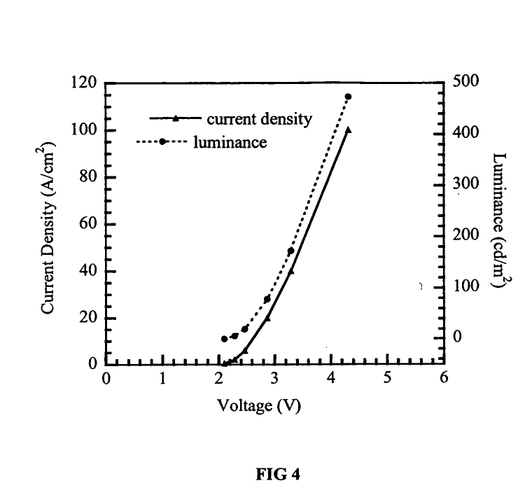

Table 1 summarizes the characterization of the polymers prepared in the present invention. Absorption (AB) and photoluminescence (PL) spectra were obtained from solid thin films of the polymers and EL spectra were obtained from ITO/PEDOT/polymer/CsF/Mg:Ag EL devices. The fabrication of EL devices was illustrated in Example 9. FIG. 2 shows EL spectra of polymer 5, 28, and 58. FIG. 3 shows AB and PL spectra of polymer 5 in dilute toluene solution and thin film. FIG. 4 And FIG. 4 shows the voltage-current-luminance characteristics of the EL device of polymer 5.

TABLE 1
Characterization of polymers according to Examples.

| Poly- | | | T_{d} | T_{g} | AB^{b} | PL^{c} | EL |
|---|---|---|---|---|---|---|---|
| mer | M_{w}^{a} | PDI | (° C.) | (° C.) | (λₘₐₓ nm) | (λₘₐₓ nm) | (λₘₐₓ nm) |
| 5 | 12200 | 1.83 | 417 | 108 | 319, 463 | 564 (460) | 552 |
| 28 | 24700 | 3.18 | 362 | 107 | 314 | 381 (310) | 584 |
| 58 | 77900 | 7.64 | 399 | 152 | 309 | 367 (310) | 556 |

^{a}weight average molecular weight, determined by size exclusion chromatography in THF using polystyrene standard.
^{b}as solid state thin film
^{c}as solid state thin film, the number in the parenthesis is the excitation wavelength.

It will be understood that organic layers in accordance with the invention can be an emissive layer or a hole injection layer or both.

The invention has been described in detail with particular reference to certain preferred embodiments thereof, but it will be understood that variations and modifications can be effected within the spirit and scope of the invention.

1. An electroluminescent device comprising:
a) a spaced-apart anode and cathode; and
b) an organic layer disposed between the spaced-apart anode and cathode and including a polymer having arylamine repeating unit moiety represented by formula 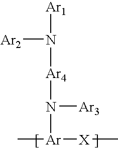
wherein:
Ar, Ar₁, Ar₂, Ar₃, and Ar₄ are each individually aryl group of from 6 to 60 carbon atoms; or a hetcroaryl group of from 4 to 60 carbons, or combinations thereof; or Ar₁ and Ar₂, Ar₃ and Ar₄, Ar₁ and Ar₄, Ar₂ and Ar₄ are connected through a chemical bond; and
X is a conjugated group having 2 to 60 carbon atoms.

2. The electroluminescent device of claim 1 wherein Ar₁ and Ar₂, Ar₃ and Ar₄, Ar₄ and Ar₄, Ar₂ and Ar₄ are connected by a chemical bond to form a group having 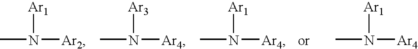
that includes the following carbazole and carbazole derivatives:

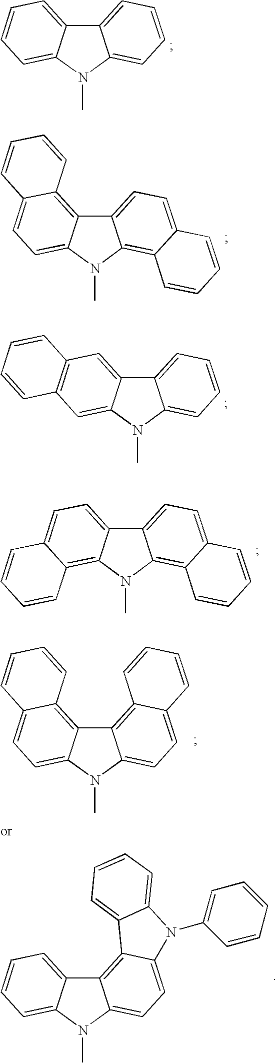

3. The electroluminescent device of claim 1 wherein X includes a plurality of groups.

4. The electroluminescent device of claim 1 wherein the organic layer is an emissive layer or a hole injection layer or both.

5. An electroluminescent device which includes an anode, a cathode, and a polymer disposed between the spaced-apart anode and cathode, the polymer being doped with one or more fluorescent dyes, phosphorescent dopants, or other light emitting material, the polymer including arylamine moiety has the repeating unit represented by formula 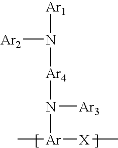
wherein:
Ar, Ar₁, Ar₂, Ar₃, and Ar₄ are each individually aryl group of from 6 to 60 carbon atoms; or a heteroaryl group of from 4 to 60 carbons, or combinations thereof; or Ar₁ and Ar₂, Ar₃ and Ar₄, Ar₁ and Ar₄, Ar₂ and Ar₄ are connected through a chemical bond; and
X is a conjugated group of from 2 to 60 carbon atoms.

6. A method of making an electrolumiiiescent device, comprising:
a) providing an anode and cathode; and
b) depositing an organic layer between the spaced-apart anode and cathode and including a polymer having arylamine moiety has the repeating unit represented formula 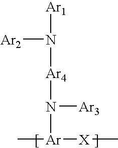
wherein:
Ar, Ar₁, Ar₂, Ar₃, and Ar₄ are each individually aryl group of from 6 to 60 carbon atoms; or a heteroaryl group of from 4 to 60 carbons or combinations thereof; or Ar₁ and Ar₂, Ar₃ and Ar₄, Ar₁ and Ar₄, Ar₂ and Ar₄ are connected through a chemical bond; and
X is a conjugated group of from 2 to 60 carbon atoms.

7. The electroluminescent device of claim 6 wherein the organic layer is an emissive layer or a hole injection layer or both.

8. The electroluminescent device of claim 1 wherein Ar, Ar₁, Ar₂, Ar₃, and Ar₄ are each phenyl.

9. The electroluminescent device of claim 5 wherein Ar, Ar₁, Ar₂, Ar₃, and Ar₄ are each phenyl.

10. The method of claim 6 wherein Ar, Ar₁, Ar₂, Ar₃, and Ar₄ are each phenyl.
